(19) United States
(12) Patent Application Publication
(10) Pub. No.: US 2025/0113619 A1
(43) Pub. Date: Apr. 3, 2025

(54) SEMICONDUCTOR DEVICE AND MANUFACTURING METHOD THEREOF

(71) Applicant: Japan Display Inc., Tokyo (JP)

(72) Inventors: Akihiro HANADA, Tokyo (JP); Hajime WATAKABE, Tokyo (JP)

(73) Assignee: Japan Display Inc., Tokyo (JP)

(21) Appl. No.: 18/890,900

(22) Filed: Sep. 20, 2024

(30) Foreign Application Priority Data
Sep. 29, 2023 (JP) 2023-170388

(51) Int. Cl. H01L 27/12; G02F 1/1368; H01L 29/786

(52) U.S. Cl. CPC H10D 86/60; H10D 30/6723; H10D 30/6734; H10D 30/6755; H10D 30/6757; H10D 86/0221; H10D 86/423; G02F 1/1368

(57) ABSTRACT

A semiconductor device includes a first gate electrode, an oxide semiconductor layer including a first oxide semiconductor having a polycrystalline structure over the first gate electrode, a source electrode and a drain electrode electrically connected to the oxide semiconductor layer, and a second gate electrode overlapping the first gate electrode and the oxide semiconductor layer over the source electrode and the drain electrode. The second gate electrode includes a second oxide semiconductor having a polycrystalline structure. The second gate electrode is electrically connected to the first gate electrode.

### CROSS-REFERENCE TO RELATED APPLICATIONS

This application claims the benefit of priority to Japanese Patent Application No. 2023-170388, filed on Sep. 29, 2023, the entire contents of which are incorporated herein by reference.

### FIELD

An embodiment of the present invention relates to a semiconductor device using an oxide semiconductor having a polycrystalline structure. An embodiment of the present invention relates to a method for manufacturing a semiconductor device using an oxide semiconductor having a polycrystalline structure.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including an oxide semiconductor film has a simple structure and can be manufactured by a low-temperature process, similar to a semiconductor device including an amorphous silicon film. Further, the semiconductor device including an oxide semiconductor film is known to have a higher field effect mobility than the semiconductor device including an amorphous silicon film.

### SUMMARY

A semiconductor device according to an embodiment of the present invention includes a first gate electrode, an oxide semiconductor layer including a first oxide semiconductor having a polycrystalline structure over the first gate electrode, a source electrode and a drain electrode electrically connected to the oxide semiconductor layer, and a second gate electrode overlapping the first gate electrode and the oxide semiconductor layer over the source electrode and the drain electrode. The second gate electrode includes a second oxide semiconductor having a polycrystalline structure. The second gate electrode is electrically connected to the first gate electrode.

A method for manufacturing a semiconductor device according to an embodiment of the present invention includes the steps of forming a first gate electrode, forming an oxide semiconductor layer including a first oxide semiconductor having a polycrystalline structure over the first gate electrode, forming a source electrode and a drain electrode each in contact with the oxide semiconductor layer, depositing a first oxide semiconductor film over the source electrode and the drain electrode, performing a heat treatment on the first oxide semiconductor film to form a second gate electrode including a second oxide semiconductor having a polycrystalline structure, and depositing a nitride layer covering the second gate electrode.

### BRIEF DESCRIPTION OF DRAWINGS

FIG. 1 is a schematic exploded perspective view showing a configuration of a display device.

FIG. 2 is a schematic plan view showing a circuit configuration of a display device.

FIG. 3 is a schematic plan view showing a configuration of a semiconductor device according to an embodiment of the present invention.

FIG. 4 is a schematic cross-sectional view showing a configuration of a semiconductor device according to an embodiment of the present invention.

FIG. 5 is a flowchart illustrating a method for manufacturing a semiconductor device according to an embodiment of the present invention.

FIG. 6 is a schematic cross-sectional view illustrating a method for manufacturing a semiconductor device according to an embodiment of the present invention.

FIG. 7 is a schematic cross-sectional view illustrating a method for manufacturing a semiconductor device according to an embodiment of the present invention.

FIG. 8 is a schematic cross-sectional view illustrating a method for manufacturing a semiconductor device according to an embodiment of the present invention.

FIG. 9 is a schematic cross-sectional view illustrating a method for manufacturing a semiconductor device according to an embodiment of the present invention.

FIG. 10 is a schematic cross-sectional view illustrating a method for manufacturing a semiconductor device according to an embodiment of the present invention.

FIG. 11 is a schematic cross-sectional view illustrating a method for manufacturing a semiconductor device according to an embodiment of the present invention.

FIG. 12 is a schematic cross-sectional view illustrating a method for manufacturing a semiconductor device according to an embodiment of the present invention.

FIG. 13 is a schematic cross-sectional view illustrating a method for manufacturing a semiconductor device according to an embodiment of the present invention.

FIG. 14 is a schematic cross-sectional view illustrating a method for manufacturing a semiconductor device according to an embodiment of the present invention.

FIG. 15 is a schematic cross-sectional view illustrating a method for manufacturing a semiconductor device according to an embodiment of the present invention.

FIG. 16 is a schematic cross-sectional view illustrating a method for manufacturing a semiconductor device according to an embodiment of the present invention.

FIG. 17 is a flowchart illustrating a method for manufacturing a semiconductor device according to an embodiment of the present invention.

FIG. 18 is a schematic cross-sectional view illustrating a method for manufacturing a semiconductor device according to an embodiment of the present invention.

FIG. 19 is a schematic cross-sectional view illustrating a method for manufacturing a semiconductor device according to an embodiment of the present invention.

FIG. 20 is a flowchart illustrating a method for manufacturing a semiconductor device according to an embodiment of the present invention.

FIG. 21 is a schematic cross-sectional view illustrating a method for manufacturing a semiconductor device according to an embodiment of the present invention.

FIG. 22 is a schematic plan view showing a configuration of a semiconductor device according to an embodiment of the present invention.

FIG. 23 is a schematic cross-sectional view showing a configuration of a semiconductor device according to an embodiment of the present invention.

FIG. 24 is a schematic plan view showing a configuration of a semiconductor device according to an embodiment of the present invention.

FIG. 25 is a schematic cross-sectional view showing a configuration of a semiconductor device according to an embodiment of the present invention.

FIG. 26 is a flowchart illustrating a method for manufacturing a semiconductor device according to an embodiment of the present invention.

FIG. 27 is a schematic cross-sectional view illustrating a method for manufacturing a semiconductor device according to an embodiment of the present invention.

FIG. 28 is a schematic cross-sectional view illustrating a method for manufacturing a semiconductor device according to an embodiment of the present invention.

FIG. 29 is a schematic cross-sectional view illustrating a method for manufacturing a semiconductor device according to an embodiment of the present invention.

FIG. 30 is a schematic cross-sectional view illustrating a method for manufacturing a semiconductor device according to an embodiment of the present invention.

FIG. 31 is a schematic cross-sectional view illustrating a method for manufacturing a semiconductor device according to an embodiment of the present invention.

FIG. 32 is a schematic plan view showing a configuration of a semiconductor device according to an embodiment of the present invention.

FIG. 33 is a schematic cross-sectional view showing a configuration of a semiconductor device according to an embodiment of the present invention.

FIG. 34 is a flowchart illustrating a method for manufacturing a semiconductor device according to an embodiment of the present invention.

FIG. 35 is a schematic cross-sectional view illustrating a method for manufacturing a semiconductor device according to an embodiment of the present invention.

FIG. 36 is a schematic cross-sectional view illustrating a method for manufacturing a semiconductor device according to an embodiment of the present invention.

FIG. 37 is a schematic cross-sectional view illustrating a method for manufacturing a semiconductor device according to an embodiment of the present invention.

FIG. 38 is a schematic cross-sectional view illustrating a method for manufacturing a semiconductor device according to an embodiment of the present invention.

FIG. 39 is a schematic cross-sectional view illustrating a method for manufacturing a semiconductor device according to an embodiment of the present invention.

### DESCRIPTION OF EMBODIMENTS

The semiconductor device is formed, for example, in a pixel of a display device. As a display device becomes more highly defined, it is necessary for the semiconductor device to not only have a high field effect mobility but also to suppress a reduction in the aperture ratio of the pixel. An embodiment of the present invention can provide a semiconductor device that suppresses a reduction in the aperture ratio of the pixel. Further, an embodiment of the present invention can provide a method for manufacturing a semiconductor device that suppresses a reduction in the aperture ratio of the pixel.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a transistor” means a positional relationship in which the semiconductor device and the pixel electrode overlap in a plan view. In addition, a plan view refers to viewing from a direction perpendicular to a surface of the substrate.

In the specification and the like, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where α includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction.

In the specification and the like, the terms “film” and “layer” can be optionally interchanged with one another.

In addition, the following embodiments can be combined with each other as long as there is no technical contradiction.

### First Embodiment

### [1. Configuration of Display Device 1]

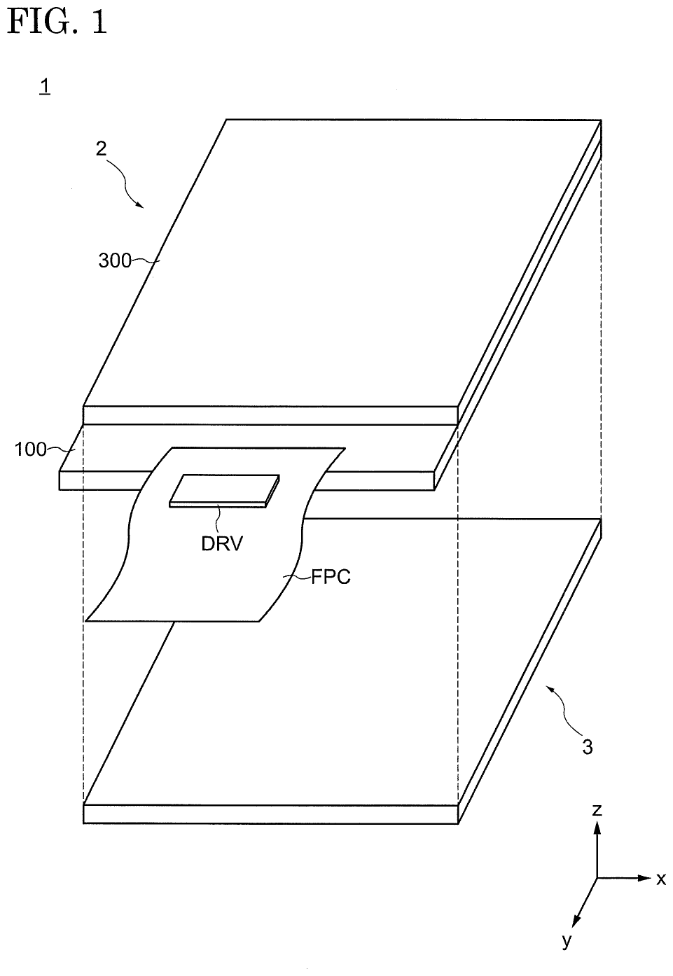

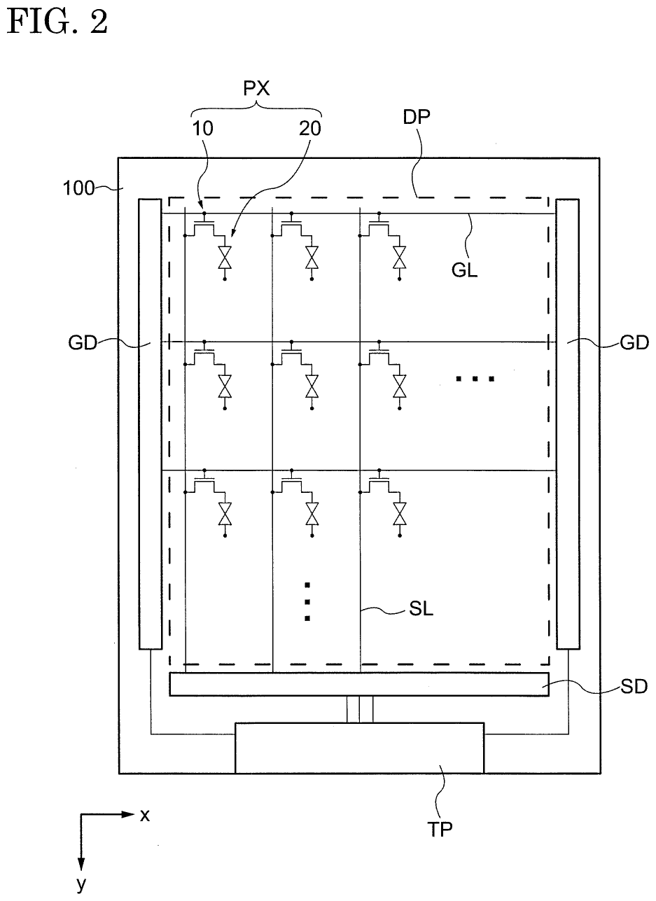

A display device 1 including a semiconductor device 10 according to an embodiment of the present invention is described with reference to FIGS. 1 and 2.

FIG. 1 is a schematic exploded perspective view showing a configuration of a display device 1. FIG. 2 is a schematic plan view showing a circuit configuration of the display device 1.

As shown in FIG. 1, the display device 1 includes a display unit 2 and a light source unit 3. In the display device 1, the light source unit 3 emits light to the display unit 2. The light source unit 3 includes, for example, a light emitting diode (LED). The light source unit 3 may include a plurality of LEDs. When a plurality of LEDs are used in the light source unit 3, LEDs having the same color may be used, or LEDs having different colors may be used. In addition, the light source unit 3 is not limited to a configuration including the LED. The light source unit 3 may include an element or device capable of emitting light. The light source unit 3 may also include a light guide plate or an optical sheet. Although the light source unit 3 is disposed below the display unit 2 in the display device 1 shown in FIG. 1, the light source unit 3 may be disposed to the side of the display unit 2.

The display unit 2 includes a first substrate 100 and a second substrate 300. A liquid crystal layer (not shown in the figures) is sandwiched between the first substrate 100 and the second substrate 300. As shown in FIG. 2, a display portion DP, a scan line driving circuit GD (the scan line driving circuit may be referred to as a gate driver), a signal line driving circuit SD (the signal line driving circuit may be referred to as a source driver), and a terminal portion TP are provided on the first substrate 100. The display portion DP is provided in the center of the first substrate 100. The scan line driving circuit GD is provided outside the display portion DP along a y direction. The signal line driving circuit SD is provided outside the display portion DP along an x direction. The terminal portion TP is provided in an edge portion of the first substrate 100.

The scan line driving circuit GD and the signal line driving circuit SD are electrically connected to the terminal portion TP. A flexible printed circuit FPC is connected to the terminal portion TP, and signals from a driving element DRV are input to the terminal portion TP (see FIG. 1). That is, the signals from the driving element DRV are input to the scan line driving circuit GD and the signal line driving circuit SD via the terminal portion TP.

The display portion DP includes a plurality of pixels PX, a plurality of scan lines GL (the scan lines may be referred to as gate lines), and a plurality of signal lines SL (the signal lines may be referred to as source lines). Each of the plurality of pixels PX is provided in a region surrounded by the scan lines GL and the signal lines SL. The scan lines GL are electrically connected to the scan line driving circuit GD and extend along the x direction. First signals generated by the scan line driving circuit GD are input to the scan lines GL. The signal lines SL are electrically connected to the signal line driving circuit SD and extend along the y direction. Second signals generated by the signal line driving circuit SD are input to the signal lines SL. Each of the plurality of pixels PX is controlled based on the first signal and the second signal.

Each of the pixels PX includes the semiconductor device 10 and a liquid crystal element 20. Although the semiconductor device 10 shown in FIG. 2 is a so-called transistor, the configuration of the semiconductor device 10 is not limited to a transistor itself. The semiconductor device 10 can be configured to include a transistor. In each of the plurality of pixels PX, the semiconductor device 10 is controlled based on the first signal and the second signal to drive the liquid crystal element 20. In the present embodiment, although the semiconductor device 10 included in the pixel PX of the display device 1 is described, the semiconductor device 10 can also be used in the scan line driving circuit GD and the signal line driving circuit SD. Further, although the display device 1 is a so-called liquid crystal display device, the display device 1 may be another display device.

### [2. Configuration of Semiconductor Device 10]

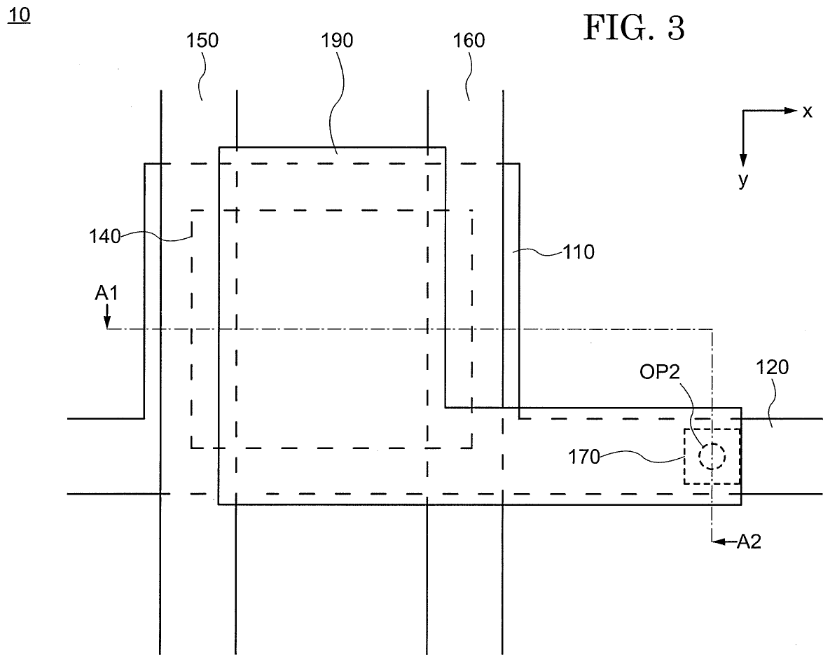

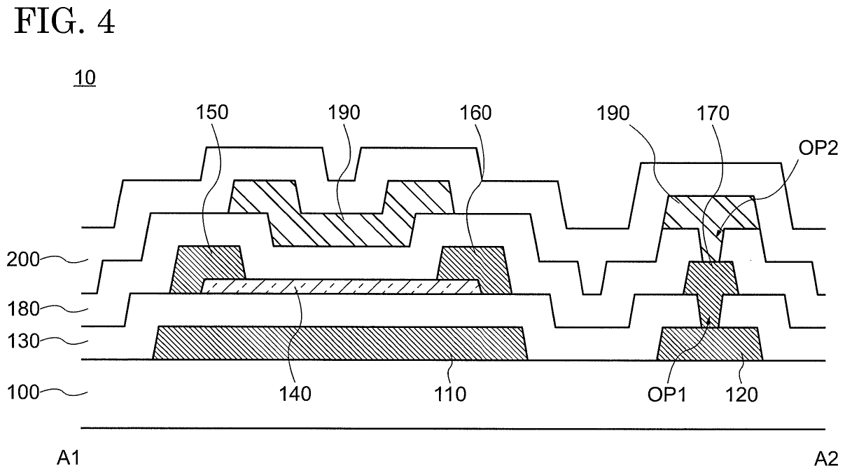

The semiconductor device 10 according to an embodiment of the present invention is described with reference to FIGS. 3 and 4.

FIG. 3 is a schematic plan view showing a configuration of the semiconductor device 10 according to an embodiment of the present invention. FIG. 4 is a schematic cross-sectional view showing a configuration of the semiconductor device 10 according to an embodiment of the present invention. FIG. 4 is a cross-sectional view of the semiconductor device 10 cut along a line A1-A2 in FIG. 3.

As shown in FIG. 4, the semiconductor device 10 includes the first substrate 100, a first gate electrode 110, a scan line 120, a first insulating layer 130, an oxide semiconductor layer 140, a source electrode 150, a drain electrode 160, a connection electrode 170, a second insulating layer 180, a second gate electrode 190, and a nitride layer 200. The first gate electrode 110 and the scan line 120 are provided on the first substrate 100. The first insulating layer 130 is provided on the first gate electrode 110 and the scan line 120 so as to cover an upper surface and a side surface of each of the first gate electrode 110 and the scan line 120. The first insulating layer 130 has a first opening portion OP1 through which a part of the upper surface of the scan line 120 is exposed. The oxide semiconductor layer 140 is provided on the first insulating layer 130 so as to overlap the first gate electrode 110. Each of the source electrode 150 and the drain electrode 160 is provided on the first insulating layer 130 so as to cover a part of an upper surface and a part of a side surface of the oxide semiconductor layer 140. The connection electrode 170 is provided on the first insulating layer 130 and is in contact with the scan line 120 through the first opening portion OP1. The second insulating layer 180 is provided on the first insulating layer 130 so as to cover the upper surface of the oxide semiconductor layer 140, an upper surface and a side surface of the source electrode 150, an upper surface and a side surface of the drain electrode 160, and an upper surface and a side surface of the connection electrode 170. The second insulating layer 180 has a second opening portion OP2 through which a part of the connection electrode 170 is exposed. The second gate electrode 190 is in contact with the connection electrode 170 through the second opening portion OP2. The nitride layer 200 is provided on the second insulating layer 180 so as to cover an upper surface and an edge surface of the second gate electrode 190.

As shown in FIG. 3, the first gate electrode 110 is provided so as to protrude in the y direction from the scan line extending in the x direction, and is formed continuously with the scan line 120. In other words, the first gate electrode is formed in the same layer as the scan line 120. Further, although the source electrode 150, the drain electrode 160, and the connection electrode 170 are provided so as to be spaced apart from each other, the source electrode 150, the drain electrode 160, and the connection electrode 170 are formed in the same layer.

The first gate electrode 110 is formed continuously with the scan line 120. In this case, it can be said that the first gate electrode 110 is electrically connected to the scan line. The second gate electrode 190 is electrically connected to the first gate electrode 110 via the connection electrode 170. Therefore, the voltage included in the signal input to the scan line 120 is applied to both the first gate electrode 110 and the second gate electrode 190.

The source electrode 150 is electrically connected to the signal line (the signal line corresponds to the signal line SL in FIG. 2 and is not shown in FIGS. 3 and 4). The drain electrode 160 is electrically connected to a pixel electrode (not shown in the figures) provided in the pixel PX. The liquid crystal layer provided between the first substrate 100 and the second substrate 300 is driven by an electric field generated between the pixel electrode provided on the first substrate 100 and a counter electrode (not shown in the figures) provided on the second substrate 300. When the liquid crystal layer is driven in each of the plurality of pixels PX, the transmission of light emitted from the light source unit 3 in each of the plurality of pixels PX is controlled. In the pixel PX, some of the components of the semiconductor device 10 shield the light emitted from the light source unit 3.

Depending on a configuration of a semiconductor device, the aperture ratio of the pixel PX may be reduced. In particular, when the size of the pixel PX becomes smaller, the reduction in the aperture ratio of the pixel PX becomes noticeable because the proportion of the semiconductor device 10 to the size of the pixel PX increases. However, since the second gate electrode 190 has light-transmitting properties in the semiconductor device 10, the reduction in the aperture ratio of the pixel PX can be suppressed.

In a plan view, the second gate electrode 190 includes a region overlapping any one of the first gate electrode 110, the scanning line 120, the source electrode 150, and the drain electrode 160 (hereinafter, referred to as an “overlapping region”), while the second gate electrode 190 also includes a region not overlapping the first gate electrode 110, the scanning line 120, the source electrode 150, and the drain electrode 160 (hereinafter, referred to as a “non-overlapping region”). Since the non-overlapping region is a region through which light emitted from the light source unit 3 transmits, the aperture ratio of the pixel PX is reduced when the non-overlapping region has light-shielding properties. However, since the second gate electrode 190 in the non-overlapping region has light-transmitting properties in the semiconductor device 10, it is possible to suppress a reduction in the aperture ratio of the pixel PX while ensuring the degree of freedom in arranging the second gate electrode 190.

Here, the details of each of the above-described components of the semiconductor device 10 are described. In addition, the detailed configuration of the oxide semiconductor layer 140 and the second gate electrode 190 is described later.

The first substrate 100 can support each layer constituting the semiconductor device 10. For example, a rigid substrate having light-transmitting properties, such as a glass substrate, a quartz substrate, or a sapphire substrate, can be used as the first substrate 100. Further, a rigid substrate having no light-transmitting properties, such as a silicon substrate, can also be used as the first substrate 100. A flexible substrate having light-transmitting properties, such as a polyimide resin substrate, an acrylic resin substrate, a siloxane resin substrate, or a fluorine resin substrate, can also be used as the first substrate 100. Impurities may be introduced into the flexible substrate in order to improve the heat resistance of the first substrate 100. In addition, the second substrate 300 can be a substrate similar to the first substrate 100.

Each of the first insulating layer 130 and the second insulating layer 180 can function as a gate insulating layer. For example, an oxide such as silicon oxide (SiOₓ), silicon oxynitride (SiOₓN_{y}), aluminum oxide (AlOₓ), or aluminum oxynitride (AlOₓN_{y}), or a nitride such as silicon nitride (SiNₓ), silicon nitride oxide (SiNₓO_{y}), aluminum nitride (AlNₓ), or aluminum nitride oxide (AlNₓO_{y}) can be used for each of the first insulating layer 130 and the second insulating layer 180. Each of the first insulating layer 130 and the second insulating layer 180 may have a single layer structure or a stacked structure.

Here, silicon oxynitride (SiOₓN_{y}) and aluminum oxynitride (AlOₓN_{y}) are oxides that contain a smaller proportion (x>y) of nitrogen (N) than oxygen (O). Further, silicon nitride oxide (SiNₓO_{y}) and aluminum nitride oxide (AlNₓO_{y}) are nitrides that contain a smaller proportion (x>y) of oxygen than nitrogen. In addition, silicon oxide (SiOₓ) and silicon oxynitride (SiOₓN_{y}) may be simply referred to as “silicon oxide” and silicon nitride (SiNₓ) and silicon nitride oxide (SiNₓO_{y}) may be simply referred to as “silicon nitride,” for convenience of explanation. Similarly, aluminum oxide (AlOₓ) and aluminum oxynitride (AlOₓN_{y}) may be simply referred to as “aluminum oxide” and aluminum nitride (AlNₓ) and aluminum nitride oxide (AlNₓO_{y}) may be simply referred to as “aluminum nitride.”

It is preferable that the oxide semiconductor layer 140 is in contact with an oxide. When the oxide semiconductor layer 140 is in contact with the oxide, oxygen can be supplied from the oxide to the oxide semiconductor layer 140 by a heat treatment. Therefore, when the first insulating layer 130 and the second insulating layer 180 each have a single-layer structure, it is preferable that silicon oxide is used for each of the first insulating layer 130 and the second insulating layer 180. Further, when the first insulating layer 130 has a stacked structure, it is preferable that the first insulating layer 130 has a structure in which silicon oxide is stacked on silicon nitride so that the silicon oxide is in contact with the oxide semiconductor layer 140. Similarly, when the second insulating layer 180 has a stacked structure, it is preferable that the second insulating layer 180 has a structure in which silicon nitride is stacked on silicon oxide so that the silicon oxide is in contact with the oxide semiconductor layer 140.

It is preferable that the first gate electrode 110 has not only conductivity but also a function of reflecting or absorbing light emitted from the light source unit 3. That is, it is preferable that the first gate electrode 110 has a light-shielding function. In a plan view, the first gate electrode 110 overlaps the entire oxide semiconductor layer 140 (see FIG. 3). Therefore, when the first gate electrode 110 has a light-shielding function, it is possible to block light incident on the oxide semiconductor layer 140. As described above, the first gate electrode 110 is formed in the same layer as the scan line 120. That is, the first gate electrode 110 is formed of the same material as the scan line 120. For example, a metal such as aluminum (Al), copper (Cu), titanium (Ti), molybdenum (Mo), or tungsten (W), or an alloy or a compound thereof can be used for the first gate electrode 110 and the scan line 120. The first gate electrode 110 and the scan line 120 may have a single layer structure or a stacked structure.

The source electrode 150, the drain electrode 160, and the connection electrode 170 have conductivity. As described above, the source electrode 150, the drain electrode 160, and the connection electrode 170 are formed in the same layer. That is, the source electrode 150, the drain electrode 160, and the connection electrode 170 are formed of the same material. The same material as the first gate electrode 110 and the scan line 120 can be used for the source electrode 150, the drain electrode 160, and the connection electrode 170.

The nitride layer 200 can function as an interlayer insulating layer. Further, although the details are described later, the nitride layer 200 can also function as a hydrogen supply layer to the second gate electrode 190. For example, a nitride such as silicon nitride (SiNₓ), silicon nitride oxide (SiNₓO_{y}), aluminum nitride (AlNₓ), or aluminum nitride oxide (AlNₓO_{y}) can be used for the nitride layer 200.

### [3. Configuration of Oxide Semiconductor Layer 140]

### [3-1. Composition of Oxide Semiconductor Layer 140]

An oxide semiconductor containing two or more metal elements including indium (In) is used for the oxide semiconductor layer 140. Gallium (Ga), zinc (Zn), aluminum (Al), hafnium (Hf), yttrium (Y), zirconium (Zr), and lanthanoids are used as a metal element other than indium.

The oxide semiconductor layer 140 has light-transmitting properties and a polycrystalline structure including a plurality of crystal grains. It is preferable to use an oxide semiconductor in which the ratio of indium to all metal elements is greater than or equal to 50% in an atomic ratio so that the oxide semiconductor layer 140 has a polycrystalline structure. When the ratio of the indium is increased, the oxide semiconductor layer 140 is easily crystallized. Further, it is preferable that gallium is included in the metal elements other than indium. Gallium belongs to the same Group 13 elements as indium. Therefore, the crystallinity of the oxide semiconductor layer 140 is hardly inhibited by gallium.

Although the details are described later, the oxide semiconductor layer 140 has properties different from a conventional oxide semiconductor having a polycrystalline structure. Therefore, in order to distinguish the oxide semiconductor included in the oxide semiconductor layer 140 from the conventional oxide semiconductor having a polycrystalline structure, the oxide semiconductor contained in the oxide semiconductor layer 140 is referred to as a Poly-crystalline Oxide Semiconductor (Poly-OS) in the following description.

The Poly-OS contained in the oxide semiconductor layer 140 can be formed by a sputtering method and a heat treatment. Here, a method for forming the oxide semiconductor layer 140 is described.

First, an oxide semiconductor film is deposited using a sputtering method. The oxide semiconductor film to be deposited has an amorphous structure. Here, the amorphous structure refers to a structure in which a long-range ordered structure does not exist and a periodic crystal lattice arrangement is not observed. For example, when the oxide semiconductor film having an amorphous structure is observed by X-ray diffraction (XRD), specific peaks due to a crystal structure are not obtained in the diffraction pattern. In addition, the oxide semiconductor film having an amorphous structure may have a short-range ordered structure in a microscopic region. However, such an oxide semiconductor film does not exhibit characteristics of Poly-OS and can be classified as the oxide semiconductor film having an amorphous structure.

The oxide semiconductor film having an amorphous structure is deposited at a low temperature. For example, the temperature of the substrate on which the oxide semiconductor film is deposited is lower than or equal to 150° C., preferably lower than or equal to 100° C., and more preferably lower than or equal to 50° C. When the temperature of the substrate is high, it is likely to generate microcrystals in the oxide semiconductor film to be deposited. Further, the oxygen partial pressure in the chamber during film formation is greater than or equal to 1% and less than or equal to 10%, preferably greater than or equal to 1% and less than or equal to 5%, and more preferably greater than or equal to 2% and less than or equal to 4%. When the oxygen partial pressure is large, microcrystals are generated in the oxide semiconductor film due to excess oxygen contained in the oxide semiconductor. On the other hand, under the condition where the oxygen partial pressure is less than 1%, the oxygen composition in the oxide semiconductor film becomes non-uniform, and an oxide semiconductor film including many microcrystals or an oxide semiconductor film that does not crystallize even when a heat treatment is performed is deposited.

Next, a heat treatment is performed on the oxide semiconductor film formed using a sputtering method. Although the heat treatment is performed in air, the atmosphere is not limited thereto. The temperature of the heat treatment is higher than or equal to 300° C. and lower than or equal to 500° C., and preferably higher than or equal to 350° C. and lower than or equal to 450° C. The time of the heat treatment is greater than or equal to 15 minutes and less than or equal to 120 minutes, and preferably greater than or equal to 30 minutes and less than or equal to 60 minutes. When the heat treatment is performed, the oxide semiconductor film having an amorphous structure is crystallized, and the oxide semiconductor layer 140 containing Poly-OS is formed.

The composition of the oxide semiconductor layer 140 is approximately the same as that of the sputtering target. Therefore, the composition of the metal elements of the oxide semiconductor layer 140 can be specified based on the composition of the metal elements of the sputtering target. The composition of the oxide semiconductor layer 140 may be specified using the XRD method. Specifically, the composition of the metal elements of the oxide semiconductor layer 140 can be specified based on the crystal structure and lattice constant of the oxide semiconductor layer 140 obtained by the XRD method. Further, the composition of the metal elements of the oxide semiconductor layer 140 can also be specified using X-ray fluorescence analysis or Electron Probe Micro Analyzer (EPMA) analysis. In addition, oxygen contained in the oxide semiconductor layer 140 is not limited thereto because oxygen changes depending on the process conditions for a sputtering method and the like.

### [3-2. Characteristics of the Oxide Semiconductor Layer 140]

Next, characteristics of the oxide semiconductor layer 140 containing Poly-OS are described.

The oxide semiconductor layer 140 has an excellent etching resistance. Specifically, the etching rate of the oxide semiconductor layer 140 is very small when the oxide semiconductor layer 140 is etched using an etching solution for wet etching. This means that the oxide semiconductor layer 140 is hardly etched by the etching solution. The etching rate when the oxide semiconductor layer 140 is etched using an etching solution containing phosphoric acid as a main component at 40° C. (hereinafter, referred to as a “mixed acid etching solution”) is less than 3 nm/min, less than 2 nm/min, or less than 1 nm/min. The ratio of phosphoric acid in the mixed acid etching solution is greater than or equal to 50%, greater than or equal to 60%, or greater than or equal to 70%. The mixed acid etching solution may contain acetic acid and nitric acid in addition to phosphoric acid. In addition, when an oxide semiconductor film not containing Poly-OS, for example, the oxide semiconductor film having an amorphous structure before the heat treatment, is etched using the mixed acid etching solution at 40° C., the etching rate of the oxide semiconductor film is greater than or equal to 100 nm/min. The etching rate when the oxide semiconductor layer 140 is etched using 0.5% of a hydrofluoric acid solution at room temperature is less than 5 nm/min, less than 4 nm/min, or less than 3 nm/min. When the oxide semiconductor film not containing Poly-OS is etched using 0.5% of the hydrofluoric acid solution at room temperature, the etching rate of the oxide semiconductor film is greater than or equal to 15 nm/min. Here, “40° C.” refers to 40±5° C. and may be the temperature of the etching solution or the set temperature of the etching solution. Further, “room temperature” refers to 25±5° C.

Examples of the oxide semiconductor layer 140 are shown in Table 1. Table 1 shows the etching rates of each of the prepared samples with respect to a mixed acid etching solution (“Mixed Acid AT-2F” manufactured by Rasa Kogyo Co., Ltd., in which the ratio of phosphoric acid in the mixed acid etching solution is 65%) and 0.5% of a hydrofluoric acid solution. When each sample was etched, the temperature of the mixed acid etching solution was 40° C., and the temperature of 0.5% of the hydrofluoric acid solution was room temperature (22° C.). In Table 1, Sample 1 is the oxide semiconductor layer 140 containing Poly-OS, Sample 2 is an oxide semiconductor film having an amorphous structure before the heat treatment, and Sample 3 is an oxide semiconductor film containing indium gallium zinc oxide (IGZO) in which the ratio of indium is less than 50%.

TABLE 1

| | Mixed acid etching | 0.5% of hydrofluoric |
|---|---|---|
| | solution | acid solution |
| Sample 1 | <0.1 nm/min | <2 nm/min |
| Sample 2 | 111 nm/min | >18 nm/min |
| Sample 3 | 162 nm/min | — |

As shown in Table 1, Sample 1 (oxide semiconductor layer 140 containing Poly-OS) is hardly etched using the mixed acid etching solution, and is etched at only 2 nm/min at most even when 0.5% of the hydrofluoric acid solution is used. When etching using the mixed acid etching solution, the etching rate of Sample 1 is less than or equal to 1/100 of the etching rate of Sample 2 (oxide semiconductor film having an amorphous structure before the heat treatment). When etching using 0.5% of the hydrofluoric acid solution, the etching rate of Sample 1 is less than or equal to approximately 1/10 of the etching rate of Sample 2. Further, when etching using the mixed acid etching solution, the etching rate of Sample 1 is less than or equal to 1/100 of the etching rate of Sample 3 (oxide semiconductor film containing IGZO in which the ratio of indium is less than 50%). That is, Sample 1 has significantly better etching resistance than Samples 2 and 3.

Such an excellent etching resistance of the oxide semiconductor layer 140 containing the Poly-OS is a characteristic that cannot be obtained with the conventional oxide semiconductor having a polycrystalline structure, which is manufactured by a process in which the temperature is lower than or equal to 500° C. Although the detailed mechanism of the excellent etching resistance of the oxide semiconductor layer 140 containing the Poly-OS is unclear, it is considered that the Poly-OS has a polycrystalline structure different from that of a conventional oxide semiconductor.

As described above, the oxide semiconductor layer 140 containing the Poly-OS has a very low etching rate with respect to an etching solution. Therefore, it is very difficult to pattern the oxide semiconductor layer 140. Thus, when the oxide semiconductor layer 140 is formed in an island shape, the oxide semiconductor film having an amorphous structure before the heat treatment is patterned in an island shape, and then the oxide semiconductor film is crystallized by performing the heat treatment. In this way, the island-shaped oxide semiconductor layer 140 containing the Poly-OS can be formed.

### [4. Configuration of Second Gate Electrode 190]

When Poly-OS includes many oxygen deficiencies, carriers are generated. Further, when hydrogen is trapped in the oxygen deficiencies, carriers are also generated. Thus, the Poly-OS including oxygen deficiencies and hydrogen has conductivity. Furthermore, the Poly-OS having conductivity has light-transmitting properties. Therefore, the Poly-OS having conductivity can be used as a transparent conductive material. In the present embodiment, the Poly-OS having conductivity is used for the second gate electrode 190. The same material as the oxide semiconductor layer 140 can be used for the second gate electrode 190. That is, an oxide semiconductor containing two or more metal elements including indium (In) is used for the second gate electrode 190 Further, the second gate electrode 190 has a polycrystalline structure.

Although the details are described later, the second gate electrode 190 containing the Poly-OS having conductivity can be formed by generating oxygen deficiencies and supplying hydrogen. The sheet resistance of the second gate electrode 190 is less than or equal to 1000 Ω/sq., preferably less than or equal to 500 Ω/sq., and more preferably less than or equal to 250 Ω/sq. The thickness of the second gate electrode 190 is, for example, greater than or equal to 30 nm and less than or equal to 200 nm, preferably greater than or equal to 50 nm and less than or equal to 180 nm, and more preferably greater than or equal to 100 nm and less than or equal to 150 nm. When the thickness of the second gate electrode 190 is less than 30 nm, the resistance of the second gate electrode 190 is not sufficiently reduced. When the thickness of the second gate electrode 190 is greater than 200 nm, the second gate electrode 190 may include a region where no oxygen deficiencies are generated, so that the resistance of the second gate electrode 190 cannot be sufficiently reduced. Therefore, it is preferable that the thickness of the second gate electrode 190 is within the above range.

### [4. Manufacturing Method of Semiconductor Device 10]

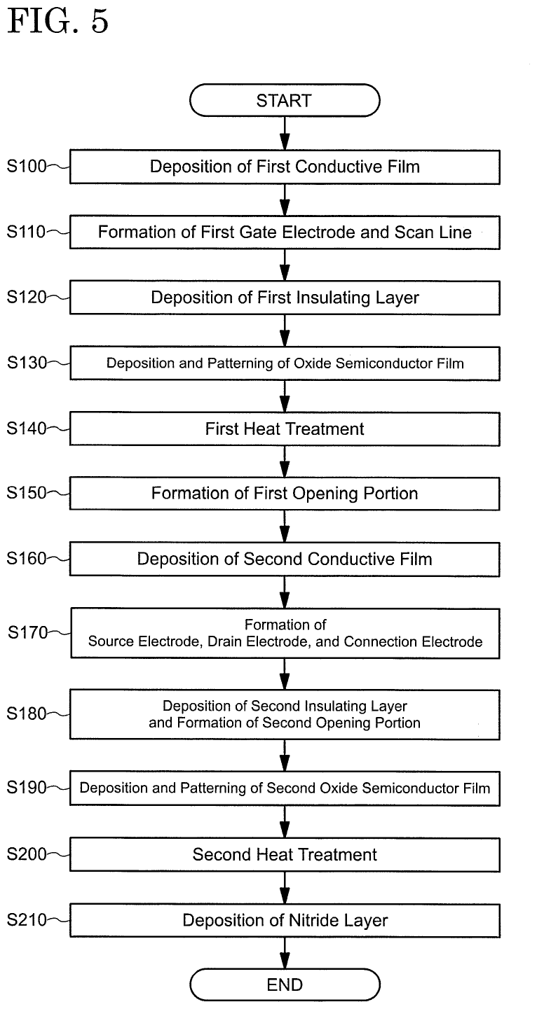

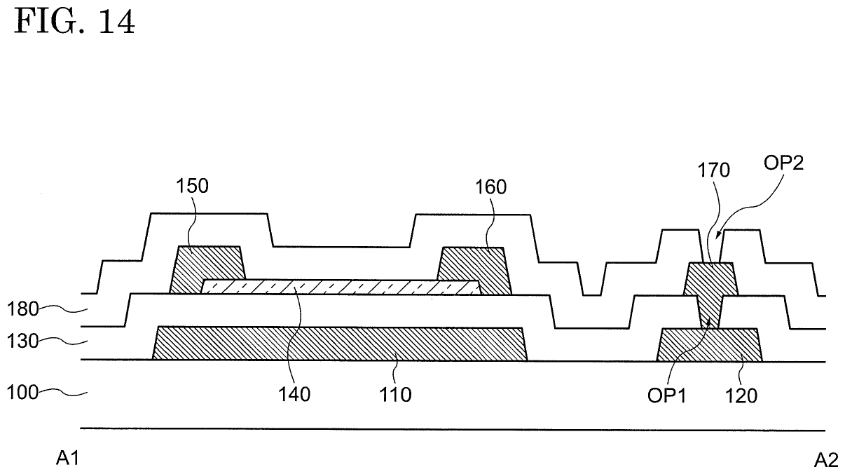

A method for manufacturing the semiconductor device 10 is described with reference to FIGS. 5 to 16.

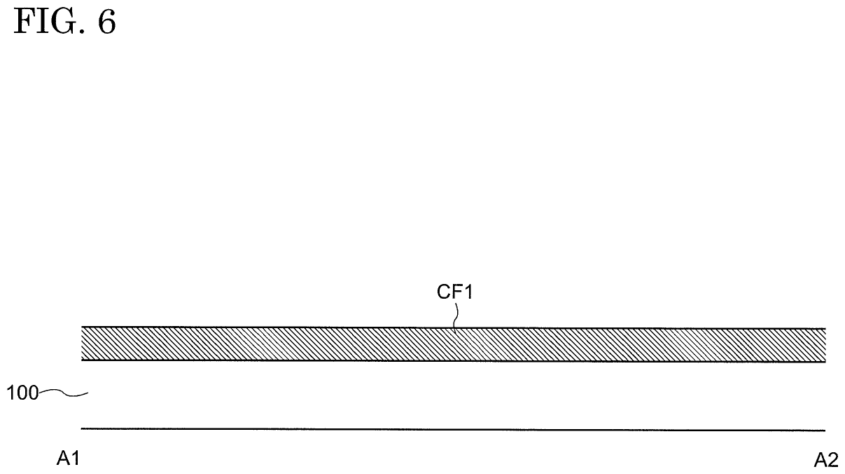

FIG. 5 is a flowchart illustrating a method for manufacturing the semiconductor device 10 according to an embodiment of the present invention. FIGS. 6 to 16 are schematic cross-sectional views illustrating a method for manufacturing the semiconductor device 10 according to an embodiment of the present invention. In the following description, each step of the flowchart shown in FIG. 5 is described in order.

In step S100, a first conductive film CF1 is deposited on the first substrate 100 using a sputtering method (see FIG. 6).

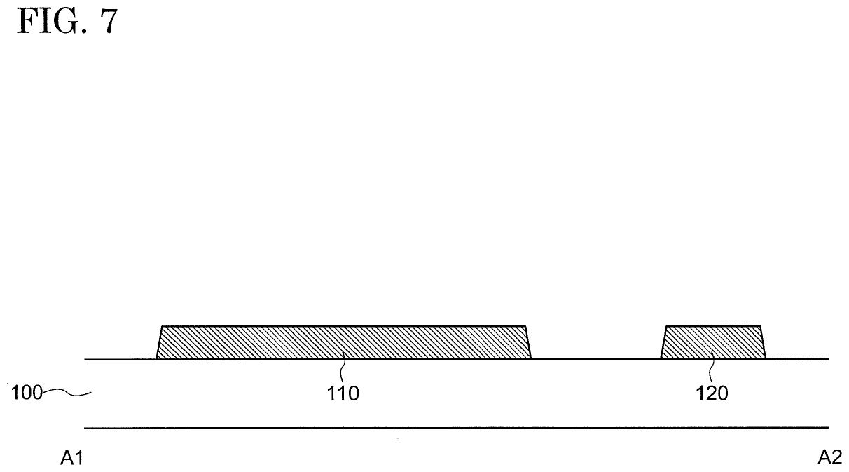

In step S110, the first conductive film CF1 is patterned using a photolithography method to form the first gate electrode 110 and the scan line 120 (see FIG. 7).

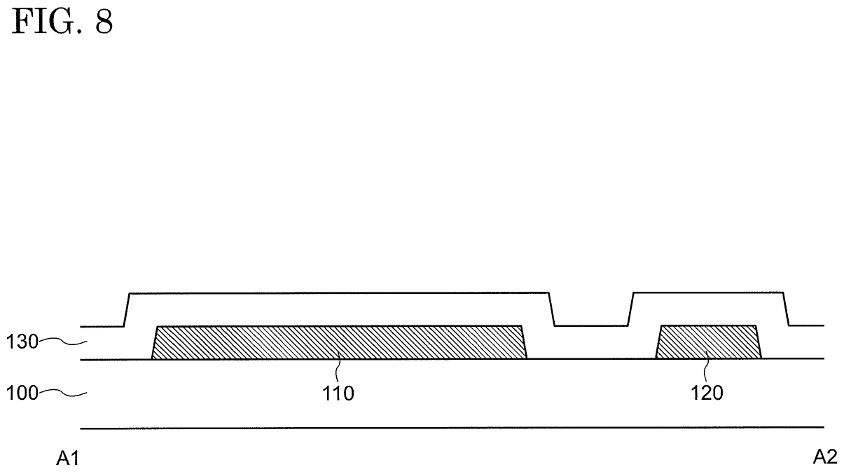

In step S120, the first insulating layer 130 is deposited using a CVD method so as to cover the first gate electrode 110 and the scan line 120 (see FIG. 8).

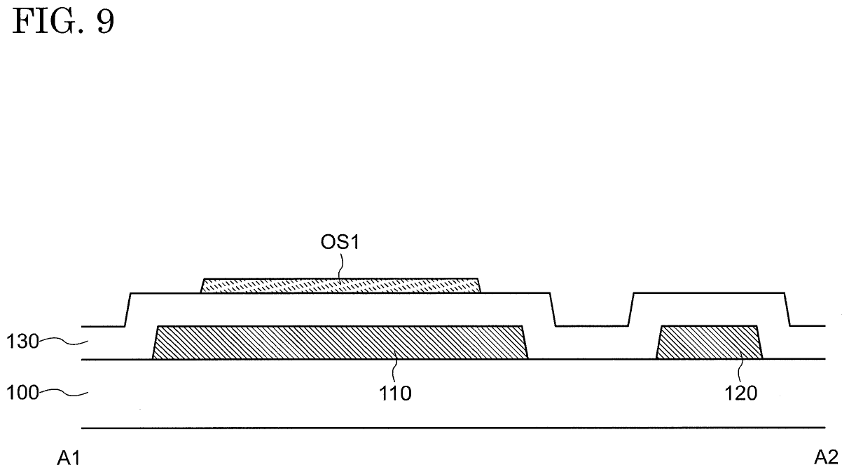

In step S130, an oxide semiconductor film OS1 is deposited on the first insulating layer 130 using a sputtering method. The conditions for depositing oxide semiconductor film OS1 are as described above. Since the oxide semiconductor film OS1 has an amorphous structure, it is easy to etch the oxide semiconductor film OS1. Therefore, the oxide semiconductor film OS1 is patterned using a photolithography method (see FIG. 9).

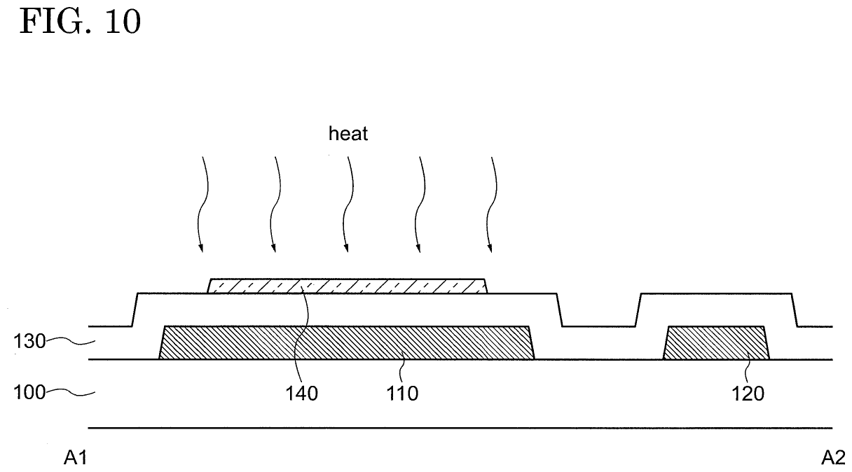

In step S140, a first heat treatment is performed on the oxide semiconductor film OS1 under the conditions described above. When the first heat treatment is performed, the oxide semiconductor film OS1 is crystallized to form the oxide semiconductor layer 140 containing Poly-OS (see FIG. 10).

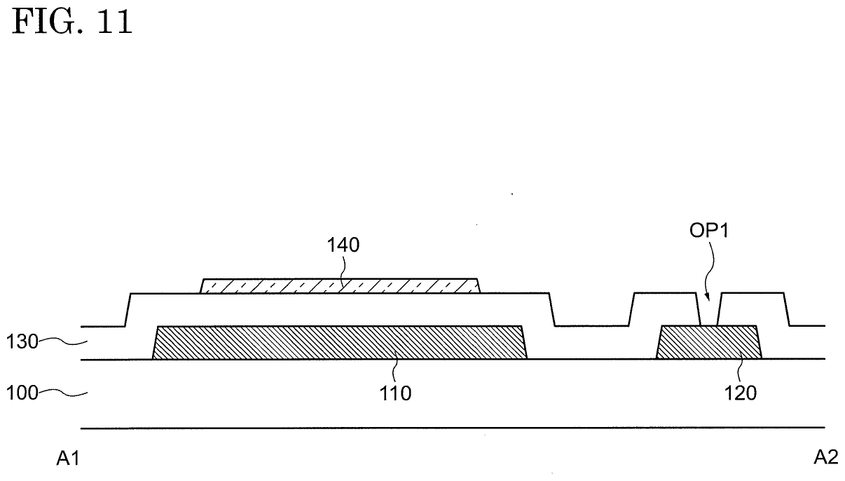

In step S150, a first opening portion OP1 is formed in the first insulating layer 130 using a photolithography method (see FIG. 11). A part of the scan line 120 is exposed in the first opening portion OP1.

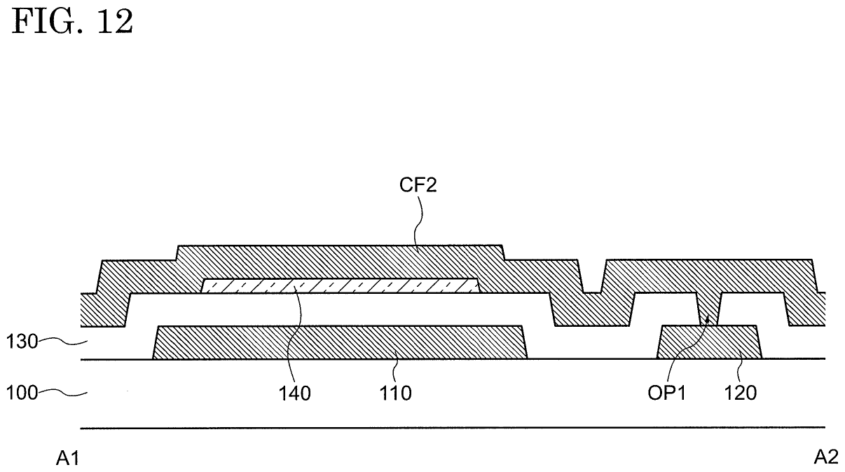

In step S160, a second conductive film CF2 is deposited using a sputtering method to cover the oxide semiconductor layer 140 and the first opening portion OP1 (see FIG. 12). For example, the second conductive film CF2 is a stacked film including titanium and aluminum (Ti/Al/Ti film).

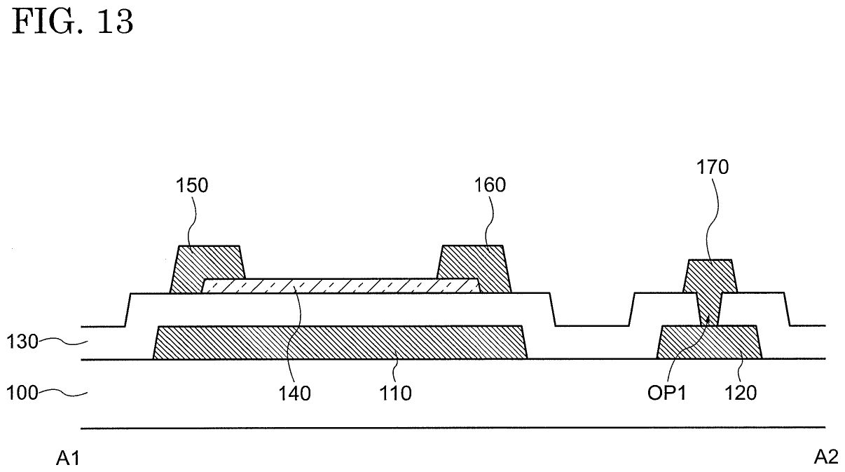

In step S170, the second conductive film CF2 is patterned using a photolithography method to form the source electrode 150, the drain electrode 160, and the connection electrode 170 (see FIG. 13). The source electrode 150 and the drain electrode 160 are in contact with the oxide semiconductor layer 140, and the connection electrode 170 is in contact with the scan line 120 through the first opening portion OP1. It is preferable that the etching of the second conductive film CF2 is wet etching using an etching solution. As described above, the oxide semiconductor layer 140 containing the Poly-OS has excellent etching resistance. Therefore, when the second conductive film CF2 is etched using the etching solution, the oxide semiconductor layer 140 is hardly etched. Therefore, in the oxide semiconductor layer 140, the difference between the thickness of a first region in contact with one of the source electrode 150 and the drain electrode and the thickness of a second region not in contact with the source electrode 150 and the drain electrode is less than or equal to 3 nm. When the conditions for the etching are adjusted, it is possible that the difference between the thickness of the first region and the thickness of the second region is less than or equal to 2 nm, preferably less than or equal to 1 nm, and more preferably less than or equal to 0.5 nm.

In step S180, the second insulating layer 180 is deposited using a CVD method. Further, the second opening portion OP2 is formed in the second insulating layer 180 using a photolithography method. A part of the connection electrode 170 is exposed in the second opening portion OP2.

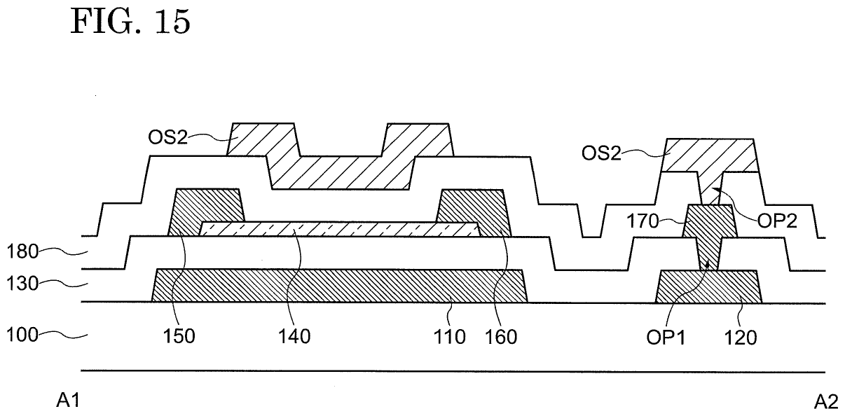

In step S190, an oxide semiconductor film OS2 is deposited on the second insulating layer 180 using a sputtering method. The conditions for depositing the oxide semiconductor film OS2 are as described above. Since the oxide semiconductor film OS2 has an amorphous structure, it is easy to etch the oxide semiconductor film OS2. Therefore, the oxide semiconductor film OS2 is patterned using a photolithography method (see FIG. 15).

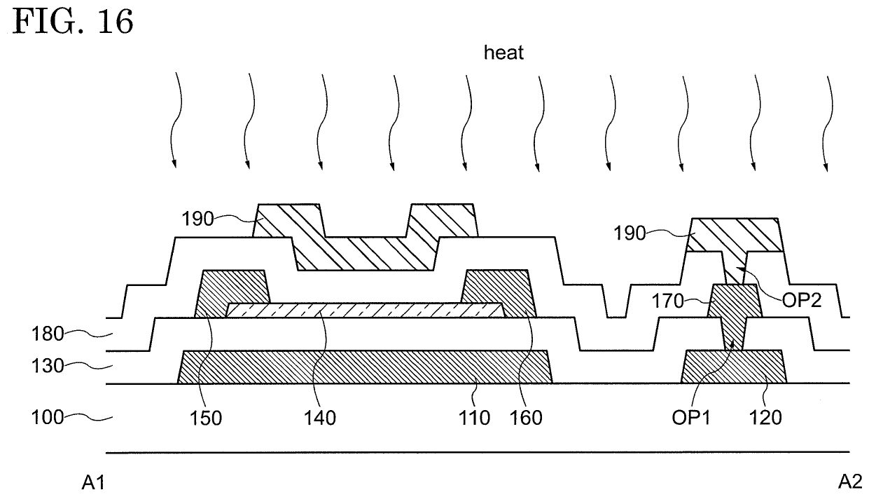

In step S200, a second heat treatment is performed on the oxide semiconductor layer 140 and the oxide semiconductor film OS2. Oxygen deficiencies may be generated in the oxide semiconductor layer 140 due to a process performed after the formation of the oxide semiconductor layer 140. When the second heat treatment is performed, oxygen is supplied from the first insulating layer 130 and the second insulating layer 180 to the oxide semiconductor layer 140, so that the oxygen deficiencies are repaired. In particular, in the second heat treatment, since the oxide semiconductor film OS2 is formed on the second insulating layer 180 so as to overlap the oxide semiconductor layer 140, the oxide semiconductor film OS2 suppresses the oxygen in the second insulating layer 180 from being released to the outside, and the oxygen can be efficiently supplied to the oxide semiconductor layer 140. Further, the oxide semiconductor film OS2 is crystallized by the second heat treatment, and the second gate electrode 190 containing Poly-OS is formed (see FIG. 16). However, the second gate electrode 190 formed in step S200 may not have a sufficiently low resistance. Therefore, in order to reduce the resistance of the second gate electrode 190, step S210 is performed.

In step S210, the nitride layer 200 is deposited using a CVD method, a sputtering method, or an ALD method. It its preferable that silicon nitride is used for the nitride layer 200. Although silicon nitride is deposited using a CVD method, oxygen deficiencies are generated in the second gate electrode 190 by reactive gases present in the chamber. Further, many gases used in the CVD method include hydrogen, and a lot of hydrogen is present in the chamber during film deposition. Furthermore, the first substrate 100 is heated in the CVD method. Therefore, when silicon nitride is deposited on the second gate electrode 190 in step S210, oxygen deficiencies are generated in the second gate electrode 190, and hydrogen is diffused into the second gate electrode 190 and trapped in the oxygen deficiencies. As a result, the second gate electrode 190 has a sufficiently low resistance. When the second gate electrode 190 is not sufficiently reduced in resistance only by depositing the nitride layer 200, a heat treatment may be performed after step S210. Since the second gate electrode 190 is in contact with the nitride layer 200, oxygen in the second gate electrode 190 is extracted by the nitride layer 200 by the heat treatment to generate oxygen deficiencies in the second gate electrode 190. Further, hydrogen contained in the nitride layer 200 is diffused into the second gate electrode 190 by the heat treatment. As a result, the second gate electrode 190 is further reduced in resistance.

The semiconductor device 10 shown in FIGS. 3 and 4 is manufactured by the above-described steps. The semiconductor device 10 manufactured in this manner has a high field effect mobility greater than or equal to 30 cm²/Vs.

In the semiconductor device 10, since the second gate electrode 190 has light-transmitting properties, it is possible to suppress a reduction in the aperture ratio of the pixel PX. Further, according to the manufacturing method of the semiconductor device 10, it is possible to repair oxygen deficiencies in the oxide semiconductor layer 140 containing Poly-OS and reduce the resistance of the second gate electrode 190 containing Poly-OS by a single heat treatment. Therefore, it is possible to suppress the manufacturing cost of the semiconductor device 10. Further, since the oxide semiconductor layer 140 contains Poly-OS and has an excellent etching resistance, the oxide semiconductor layer 140 has stable properties not only during the manufacture of the semiconductor device 10 but also after the manufacture. Therefore, the semiconductor device 10 has high reliability.

### First Modification of First Embodiment

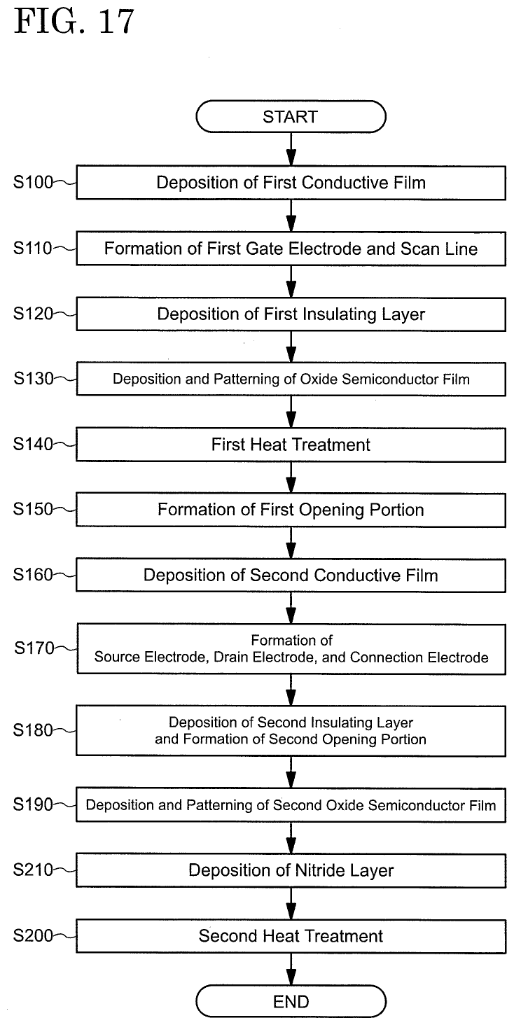

A modification of the method for manufacturing the semiconductor device 10 is described with reference to FIGS. 17 to 19. In addition, hereinafter, the description of the same configuration as the semiconductor device 10 may be omitted.

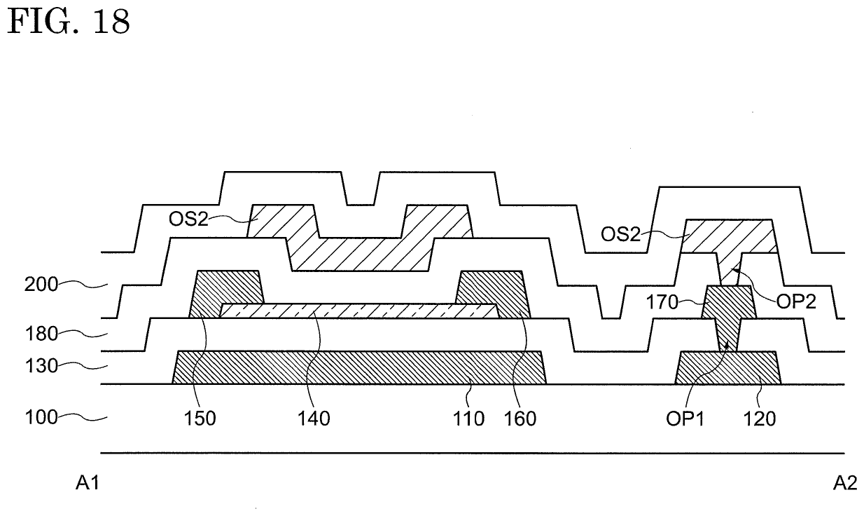

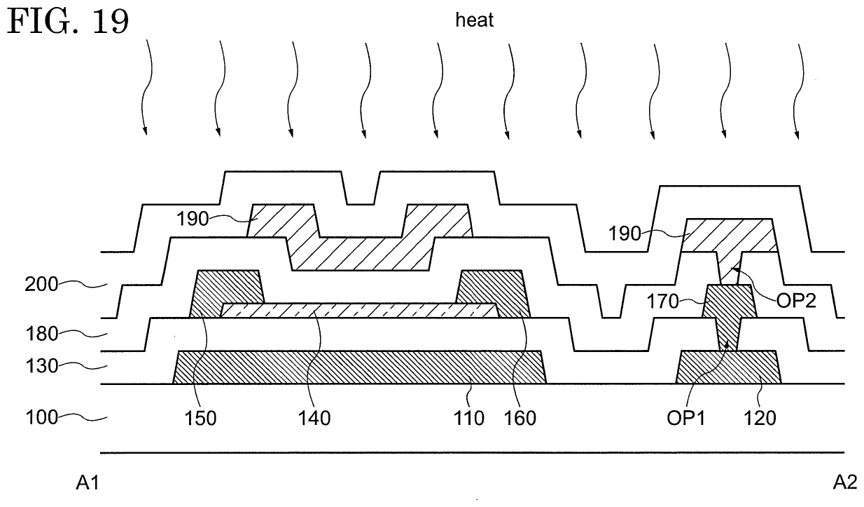

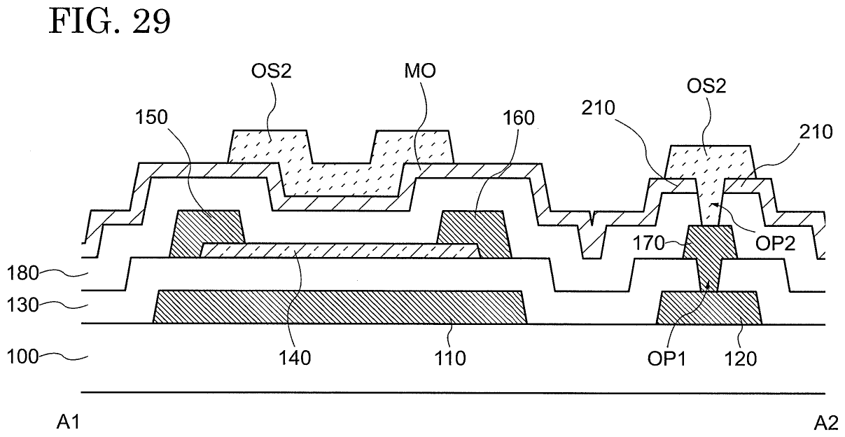

FIG. 17 is a flowchart illustrating a method for manufacturing the semiconductor device 10 according to an embodiment of the present invention. FIGS. 18 and 19 are schematic cross-sectional views illustrating a method for manufacturing the semiconductor device 10 according to an embodiment of the present invention. In the following description, each step of the flowchart shown in FIG. 29 is described in order.

Since steps S100 to S190 are similar to those described with reference to FIG. 5, the description thereof is omitted here. In the present modification, step S210 is performed after step S190 and before step S200.

In step S210, a nitride layer 200 is deposited using a CVD method, a sputtering method, or an ALD method. In step S210 of the present modification, the nitride layer 200 is deposited on the oxide semiconductor film OS2 having an amorphous structure. When the nitride layer 200 is deposited, oxygen deficiencies are generated in the oxide semiconductor film OS2, and hydrogen is trapped in the generated oxygen deficiencies. Step S200 is performed after step S210.

In step S200, a second heat treatment is performed on the oxide semiconductor layer 140 and the oxide semiconductor film OS2. In the second heat treatment, since the oxide semiconductor film OS2 is formed on the second insulating layer 180 so as to overlap the oxide semiconductor layer 140, the oxide semiconductor film OS2 suppresses the oxygen in the second insulating layer 180 from being released to the outside, and the oxygen can be efficiently supplied to the oxide semiconductor layer 140. When the second heat treatment is performed, the oxide semiconductor film OS2 is crystalized to form the second gate electrode 190 containing Poly-OS (see FIG. 19). In step S200 of the present modification, since hydrogen is trapped in oxygen deficiencies in the oxide semiconductor film OS2, the oxygen deficiencies are difficult to repair. Therefore, the second gate electrode 190 is reduced in resistance.

The semiconductor device 10 shown in FIGS. 3 and 4 is manufactured by the above-described steps. The semiconductor device 10 manufactured in this manner also has a high field effect mobility greater than or equal to 30 cm²/Vs.

Also in the semiconductor device 10 manufactured in the present modification, since the second gate electrode 190 has light-transmitting properties, it is possible to suppress a reduction in the aperture ratio of the pixel PX. Further, according to the manufacturing method of the semiconductor device 10 in the present modification, it is possible to repair oxygen deficiencies in the oxide semiconductor layer 140 containing Poly-OS and reduce the resistance of the second gate electrode 190 containing Poly-OS by a single heat treatment. Therefore, it is possible to suppress the manufacturing cost of the semiconductor device 10. Further, since the oxide semiconductor layer 140 contains Poly-OS and has an excellent etching resistance, the oxide semiconductor layer 140 has stable properties not only during the manufacture of the semiconductor device 10 but also after the manufacture. Therefore, the semiconductor device 10 has high reliability.

### Second Modification of First Embodiment

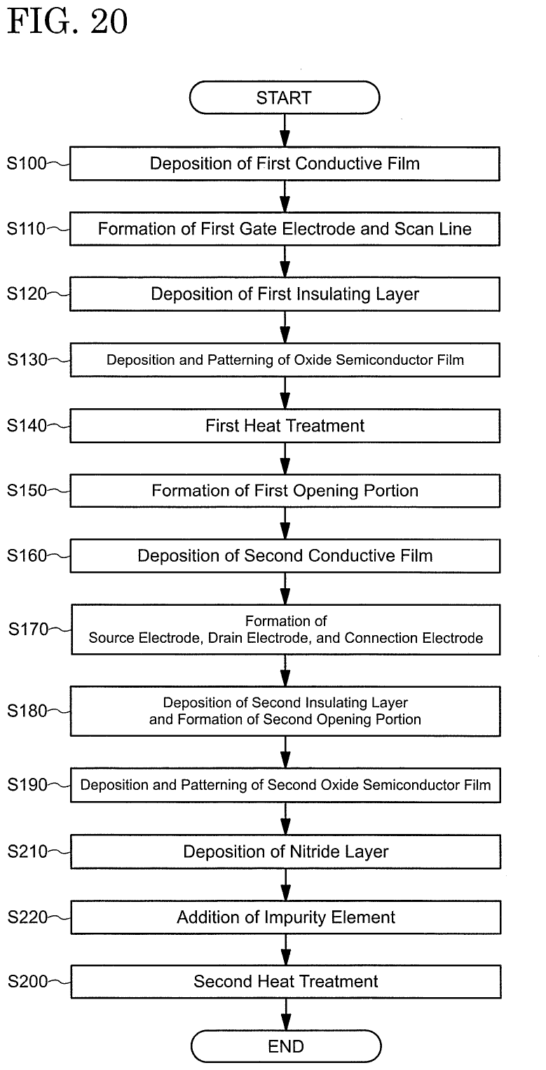

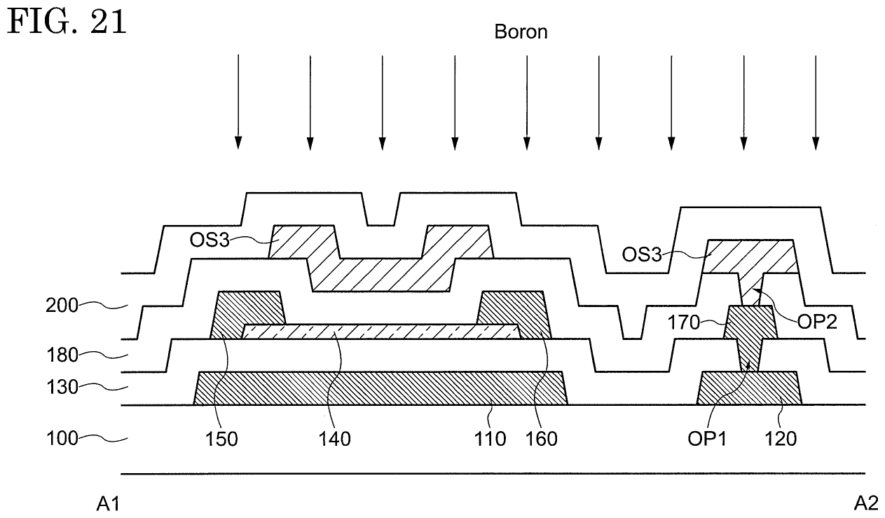

Another modification of the method for manufacturing the semiconductor device 10 is described with reference to FIGS. 20 and 21. In addition, hereinafter, the description of the same configuration as the semiconductor device 10 may be omitted.

FIG. 20 is a flowchart illustrating a method for manufacturing the semiconductor device 10 according to an embodiment of the present invention. FIG. 21 is a schematic cross-sectional view illustrating a method for manufacturing the semiconductor device 10 according to an embodiment of the present invention. In the following description, each step of the flowchart shown in FIG. 29 is described in order.

Since steps S100 to S190 are similar to those described with reference to FIG. 17, the description thereof is omitted here. In the present modification, step S220 is performed after step S210 and before step S200.

In step S220, an impurity element is added to the oxide semiconductor film OS2 using an ion implantation method to form an oxide semiconductor film OS3 containing the impurity element and having an amorphous structure (see FIG. 21). The impurity element is added to the oxide semiconductor film OS2 through the nitride layer 200. For example, although the impurity element is boron (B) or phosphorus (P), the impurity element is not limited thereto. Oxygen deficiencies are generated in the oxide semiconductor film OS3 to which the impurity element is added. Step S200 is performed after step S220.

In step S200, a second heat treatment is performed on the oxide semiconductor layer 140 and the oxide semiconductor film OS3. The oxide semiconductor film OS2 is crystallized by the second heat treatment, and the second gate electrode 190 containing Poly-OS is formed. In addition, the second gate electrode 190 contains the impurity element. In the Poly-OS in which oxygen deficiencies are generated and which contains the impurity element, the oxygen deficiencies are difficult to repair by the impurity element. Further, since hydrogen is trapped in the oxygen deficiencies, the oxygen deficiencies in the Poly-OS are stabilized. Therefore, the conductivity of the second gate electrode 190 containing the Poly-OS including the impurity element is stabilized.

The semiconductor device 10 shown in FIGS. 3 and 4 is manufactured by the above-described steps. The semiconductor device 10 manufactured in this manner also has a high field effect mobility greater than or equal to 30 cm²/Vs.

Also in the semiconductor device 10 manufactured in the present modification, since the second gate electrode 190 has light-transmitting properties, it is possible to suppress a reduction in the aperture ratio of the pixel PX. Further, according to the manufacturing method of the semiconductor device 10 in the present modification, it is possible to repair oxygen deficiencies in the oxide semiconductor layer 140 containing Poly-OS and reduce the resistance of the second gate electrode 190 containing Poly-OS by a single heat treatment. Therefore, it is possible to suppress the manufacturing cost of the semiconductor device 10. Further, since the oxide semiconductor layer 140 contains Poly-OS and has an excellent etching resistance, the oxide semiconductor layer 140 has stable properties not only during the manufacture of the semiconductor device 10 but also after the manufacture. Therefore, the semiconductor device 10 has high reliability.

### Third Modification of First Embodiment

A semiconductor device 10A which is a modification of the semiconductor device 10 is described. In addition, hereinafter, the description of the same configuration as the semiconductor device 10 may be omitted.

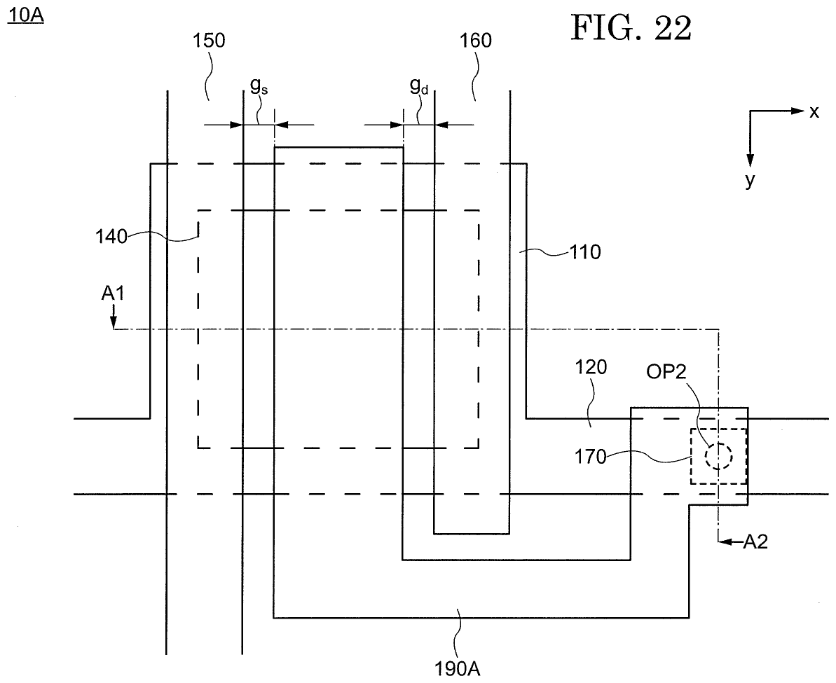

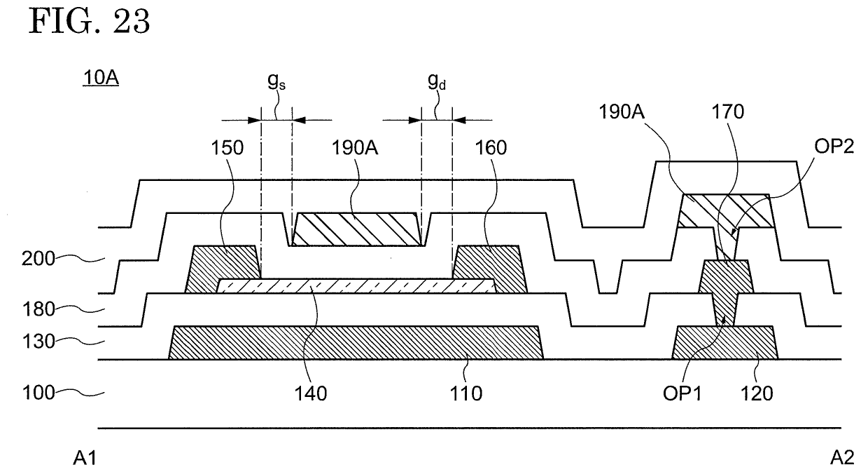

FIG. 22 is a schematic plan view showing a configuration of the semiconductor device 10A according to an embodiment of the present invention. FIG. 23 is a schematic plan view showing a configuration of the semiconductor device 10A according to an embodiment of the present invention.

In a plan view, the second gate electrode 190A is located between the source electrode 150 and the drain electrode 160. The second gate electrode 190A is arranged with a gap gₛ from the source electrode 150 and with a gap g_{d} from the drain electrode 160. Here, the gap gₛ is a distance from one edge surface of the second gate electrode 190A to an edge surface of the source electrode 150, and the gap g_{d} is a distance from the other edge surface of the second gate electrode 190A to an edge surface of the drain electrode 160. The gap gₛ may be the same as the gap g_{d}, or may be different from the gap g_{d}. Each of the gap gₛ and the gap g_{d} is greater than or equal to 0.1 μm and less than or equal to 2.0 μm, preferably greater than or equal to 0.3 μm and less than or equal to 1.5 μm, and more preferably greater than or equal to 0.5 μm and less than or equal to 1.0 μm. In the semiconductor device 10A, the occurrence of an inter-electrode short circuit between the second gate electrode 190A and the source electrode 150 or the drain electrode 160 can be suppressed by the gap gₛ and the gap g_{d}. In the semiconductor device 10A, since the first gate electrode 110 overlaps regions corresponding to the gap gₛ and the gap g_{d} in the oxide semiconductor layer 140, a channel is also formed in the regions. When each of the gap gₛ and the gap g_{d} is smaller than 0.1 μm, an inter-electrode short circuit is likely to occur between the second gate electrode 190 and the source electrode 150 or the drain electrode 160. Further, when each of the gap gₛ and the gap g_{d} is larger than 2.0 μm, the field effect mobility decreases because the current flowing through the channel decreases. Therefore, the ranges of the gap gₛ and the gap g_{d} are preferably within the above range.

As described above, the second gate electrode 190A does not overlap the source electrode 150 and the drain electrode 160 in a plan view in order to suppress the occurrence of an inter-electrode short circuit between the second gate electrode 190A and the source electrode 150 or the drain electrode 160. As shown in FIG. 22, the second gate electrode 190A extends so as to surround an edge portion of the drain electrode 160. In addition, the second gate electrode 190A only needs to extend so as to surround an edge portion of one of the source electrode 150 and the drain electrode 160 and to be electrically connected to the scan line 120.

In the semiconductor device 10A, even when the second gate electrode 190A surrounds the edge portion of the source electrode 150 or the drain electrode 160 in a plan view and the area of the non-overlapping region is large, the second gate electrode 190A has light-transmitting properties, so that the reduction in the aperture ratio of the pixel PX can be suppressed. Further, since the second gate electrode 190A does not overlap the source electrode 150 and the drain electrode 160 in a plan view and is arranged with gaps from the source electrode 150 and the drain electrode 160, the occurrence of an inter-electrode short circuit between the electrodes can be suppressed. Therefore, the semiconductor device 10A has high reliability.

### Fourth Modification of First Embodiment

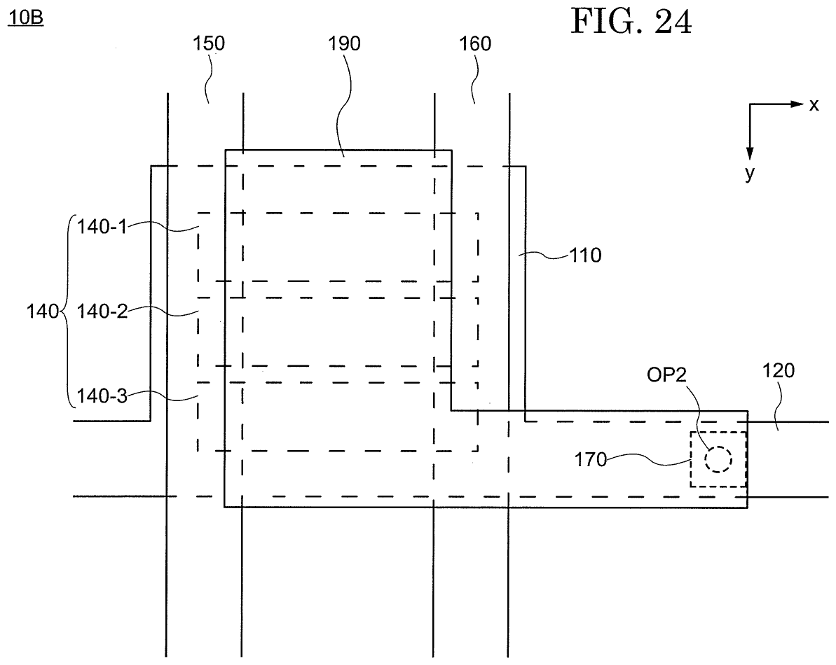

A semiconductor device 10B which is another modification of the semiconductor device 10 is described with reference to FIG. 24. In addition, hereinafter, the description of the same configuration as the semiconductor device 10 may be omitted.

FIG. 19 is a schematic plan view showing a configuration of the semiconductor device 10B according to an embodiment of the present invention.

The semiconductor device 10B includes a plurality of oxide semiconductor layers 140 (a first oxide semiconductor layer 140-1, a second oxide semiconductor layer 140-2, and a third oxide semiconductor layer 140-3). Each of the first oxide semiconductor layer 140-1 to the third oxide semiconductor layer 140-3 is formed in an island shape. That is, the first oxide semiconductor layer 140-1 to the third oxide semiconductor layer 140-3 are arranged separately from each other. In the semiconductor device 10B having a high field effect mobility, a large current flows through a channel formed in the oxide semiconductor layer 140, so that the oxide semiconductor layer 140 may generate heat. In particular, the generation of heat in the oxide semiconductor layer 140 becomes more noticeable as the area of the oxide semiconductor layer 140 becomes larger. Therefore, in the semiconductor device 10B, the area of one oxide semiconductor layer 140 is reduced and the plurality of oxide semiconductor layers 140 are arranged. This makes it possible to suppress the generation of heat in the oxide semiconductor layer 140 while maintaining the amount of current flowing through the channel.

In the semiconductor device 10B, since the second gate electrode 190 has light-transmitting properties, it is possible to suppress a reduction in the aperture ratio of the pixel PX. Further, in the semiconductor device 10B, the generation of heat in the oxide semiconductor layer 140 can be suppressed. Therefore, the semiconductor device 10B has high reliability.

### Second Embodiment

The crystallinity of the Poly-OS can be controlled using a buffer layer. In the present embodiment, a semiconductor device 11 including a buffer layer is described. In addition, hereinafter, the description of the same configuration as the semiconductor device 10 may be omitted.

### [1. Configuration of Semiconductor Device 11]

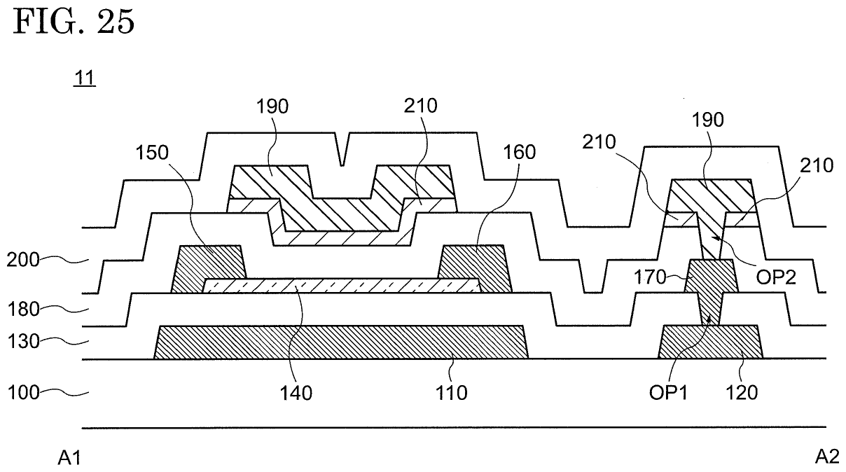

The semiconductor device 11 according to an embodiment of the present invention is described with reference to FIG. 25.

FIG. 25 is a schematic cross-sectional view showing a configuration of the semiconductor device 11 according to an embodiment of the present invention.

As shown in FIG. 25, the semiconductor device 11 includes the first substrate 100, the first gate electrode 110, the scan line 120, the first insulating layer 130, the oxide semiconductor layer 140, the source electrode 150, the drain electrode 160, the connection electrode 170, the second insulating layer 180, a metal oxide layer 210, the second gate electrode 190, and the nitride layer 200. The metal oxide layer 210 is provided on the second insulating layer 180 so as to overlap the oxide semiconductor layer 140. The second insulating layer 180 and the metal oxide layer 210 have a second opening portion OP2 through which a part of an upper surface of the connection electrode 170 is exposed. The second gate electrode 190 is provided on and in contact with the metal oxide layer 210. The second gate electrode 190 has substantially the same planar shape as the metal oxide layer 210. That is, an edge surface of the second gate electrode 190 is substantially aligned with an edge surface of the metal oxide layer 210. The second gate electrode 190 is in contact with the connection electrode 170 through the second opening portion OP2. The nitride layer 200 is provided on the second insulating layer 180 so as to cover the edge surface of the metal oxide layer 210 and the upper surface and the edge surface of the second gate electrode 190.

The metal oxide layer 210 can function as a buffer layer that improves the crystallinity of the Poly-OS contained in the second gate electrode 190. The second gate electrode 190 including the Poly-OS with improved crystallinity has further reduced resistance.

For example, a metal oxide containing aluminum as a main component is used for the metal oxide layer 210. The ratio of aluminum contained in the metal oxide layer 210 may be greater than or equal to 5% and less than or equal to 70%, greater than or equal to 10% and less than or equal to 60%, or greater than or equal to 30% and less than or equal to 50% of the entire metal oxide layer 210. The ratio may be a mass ratio or a weight ratio.

The thickness of the metal oxide layer 210 is greater than or equal to 1 nm and less than or equal to 50 nm, preferably greater than or equal to 1 nm and less than or equal to 30 nm. It is preferable that aluminum oxide is used for the metal oxide layer 210. Aluminum oxide has a high barrier property against gases such as oxygen and hydrogen. Here, the barrier property refers to the function of suppressing the permeation of gases such as oxygen and hydrogen.

In addition, a metal oxide containing a metal other than aluminum as a main component may be used for the metal oxide layer 210. For example, indium tin oxide (ITO), indium zinc oxide (IZO), indium gallium zinc oxide (IGZO), or the like may be used for the metal oxide layer 210.

### [2. Manufacturing Method of Semiconductor Device 11]

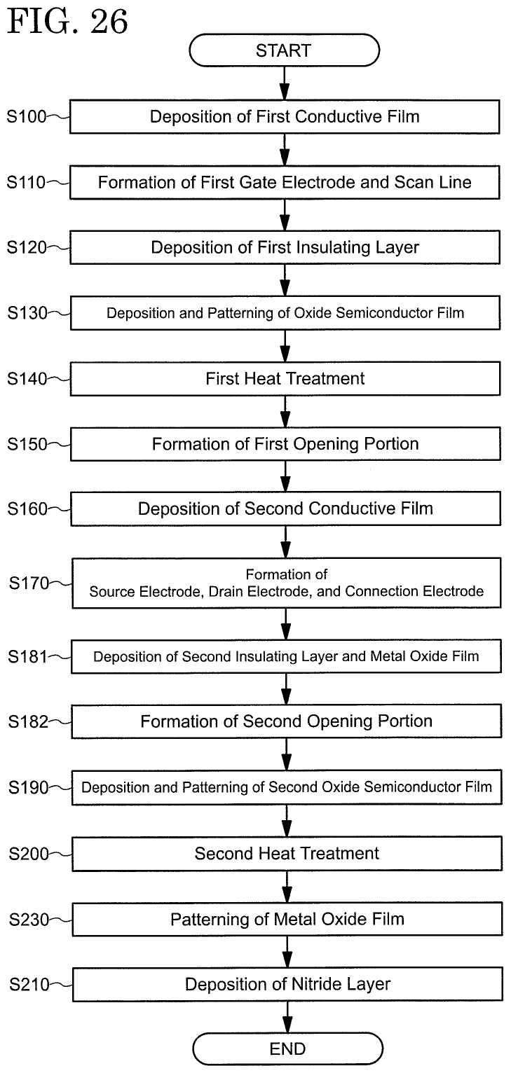

A method for manufacturing the semiconductor device 11 is described with reference to FIGS. 26 to 31.

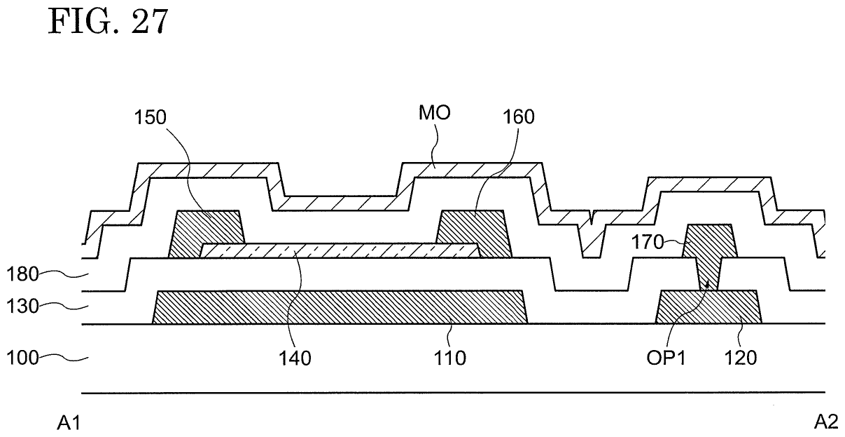

FIG. 26 is a flowchart illustrating a method for manufacturing the semiconductor device 11 according to an embodiment of the present invention. FIGS. 27 to 31 are schematic cross-sectional views illustrating a method for manufacturing the semiconductor device 11 according to an embodiment of the present invention. In the following description, each step of the flowchart shown in FIG. 26 is described in order.

Since steps S100 to S170 are similar to those described with reference to FIG. 5 in the First Embodiment, the description thereof is omitted here. In the manufacture of the semiconductor device 11, step S181 is performed after step S170.

In step S181, the second insulating layer 180 and the metal oxide film MO are deposited in this order (see FIG. 27). The second insulating layer 180 is deposited using a CVD method. The metal oxide film MO is deposited using a sputtering method or an atomic layer deposition method (ALD method). For example, the second insulating layer 180 includes silicon oxide in contact with the oxide semiconductor layer 140. Further, for example, aluminum oxide is used for the metal oxide film MO. Step S182 is performed after step S181.

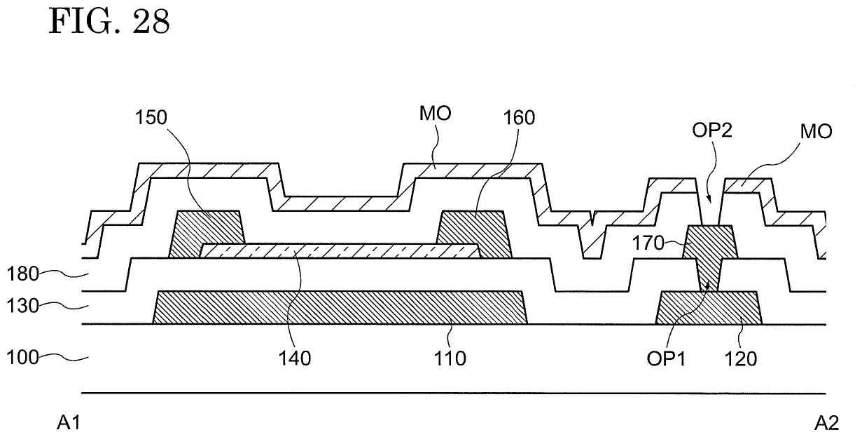

In step S182, a second opening portion OP2 is formed in the second insulating layer 180 and the metal oxide film MO using a photolithography method (see FIG. 28). A part of the connection electrode 170 is exposed in the second opening portion OP2. Step S190 is performed after step S182.

In step S190, an oxide semiconductor film OS2 is deposited on the metal oxide film MO using a sputtering method. The conditions for depositing the oxide semiconductor film OS2 are as described above. Since the oxide semiconductor film OS2 has an amorphous structure, it is easy to etch the oxide semiconductor film OS2. Therefore, the oxide semiconductor film OS2 is patterned using a photolithography method (see FIG. 29). The oxide semiconductor film OS2 is in contact with the connection electrode 170 through the second opening portion OP2. Step S200 is performed after step S190.

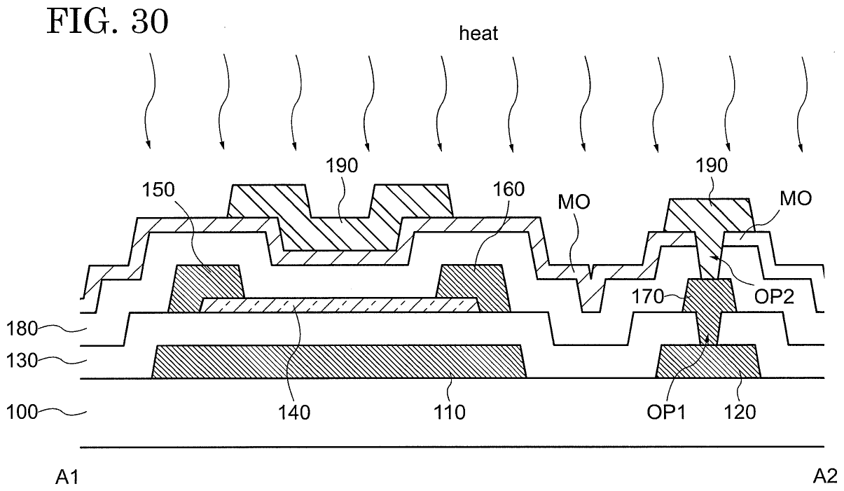

In step S200, a second heat treatment is performed on the oxide semiconductor layer 140 and the oxide semiconductor film OS2. In the second heat treatment, since the metal oxide film MO is formed so as to cover the second insulating layer 180, the metal oxide film MO suppresses oxygen in the second insulating layer 180 from being released to the outside, and oxygen can be efficiently supplied to the oxide semiconductor layer 140. Further, the oxide semiconductor film OS2 is crystallized by the second heat treatment, and the second gate electrode 190 containing Poly-OS is formed (see FIG. 30). The metal oxide film MO functions as a buffer layer and controls the crystallinity of the second gate electrode 190. Specifically, the size of the crystal grains included in the second gate electrode 190 increases, and the degree of crystallinity of the second gate electrode 190 increases. Step S230 is performed after step S200.

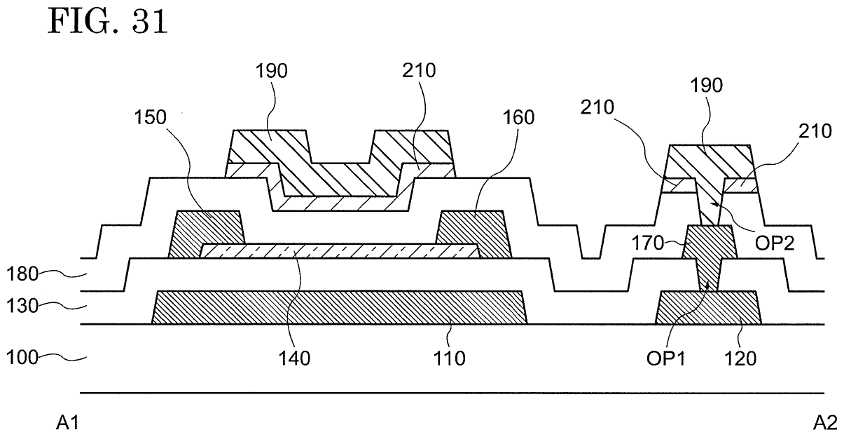

In step S230, the metal oxide film MO is patterned using the second gate electrode 190 as a mask to form the metal oxide layer 210 (see FIG. 31). The second gate electrode 190 containing Poly-OS has excellent etching resistance. Therefore, even when the metal oxide film MO is etched in the patterning of the metal oxide film MO, the second gate electrode 190 used as a mask is not etched. In the semiconductor device 11, since the second gate electrode 190 can be used as a mask in the formation of the metal oxide layer 210, a photolithography step can be omitted. Step S210 is performed after step S230.

In step S210, the nitride layer 220 is deposited using a CVD method, a sputtering method, or an ALD method. When the nitride layer 200 is deposited on the second gate electrode 190, oxygen deficiencies are generated in the second gate electrode 190, and hydrogen is diffused into the second gate electrode 190 and trapped in the oxygen deficiencies. As a result, the second gate electrode 190 has sufficiently low resistance.

The semiconductor device 11 shown in FIG. 25 is manufactured by the above-described steps. The semiconductor device 10 manufactured in this manner has a high field effect mobility greater than or equal to 30 cm²/Vs.

In the semiconductor device 11, since the second gate electrode 190 has light-transmitting properties, it is possible to suppress a reduction in the aperture ratio of the pixel PX. Further, according to the manufacturing method of the semiconductor device 11, it is possible to repair oxygen deficiencies in the oxide semiconductor layer 140 containing Poly-OS and reduce the resistance of the second gate electrode 190 containing Poly-OS by a single heat treatment. Therefore, it is possible to suppress the manufacturing cost of the semiconductor device 11. Further, the crystallinity of the second gate electrode 190 is increased by the metal oxide layer 210, and the second gate electrode 190 is stabilized. Therefore, the semiconductor device 11 has high reliability.

### Modification of Second Embodiment

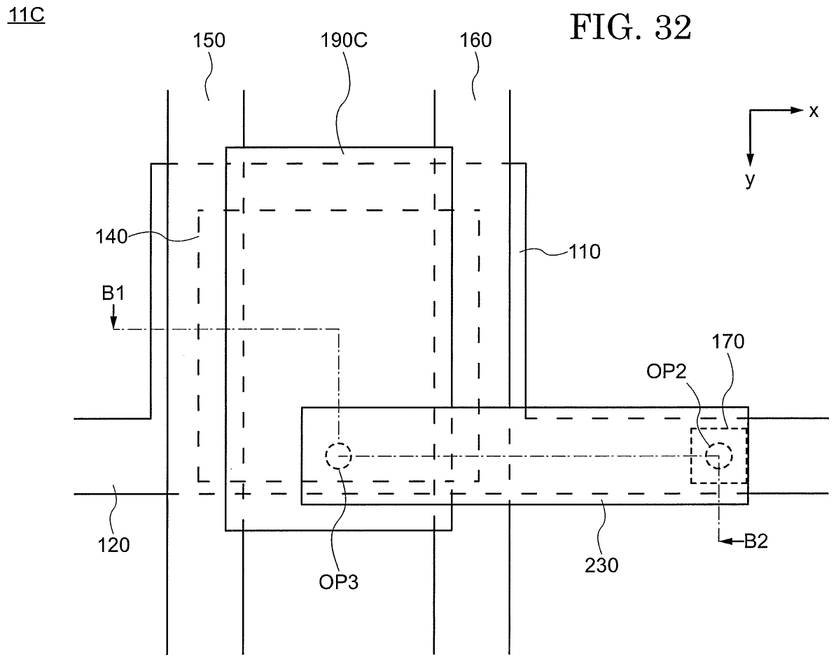

A semiconductor device 11C which is a modification of the semiconductor device 11 is described with reference to FIGS. 32 to 39. In addition, hereinafter, the description of the same configuration as the semiconductor device 11 may be omitted. Further, hereinafter, the connection electrode 170 described in the First Embodiment is described as a first connection electrode 170, for convenience of description.

### [1. Configuration of Semiconductor Device 11C]

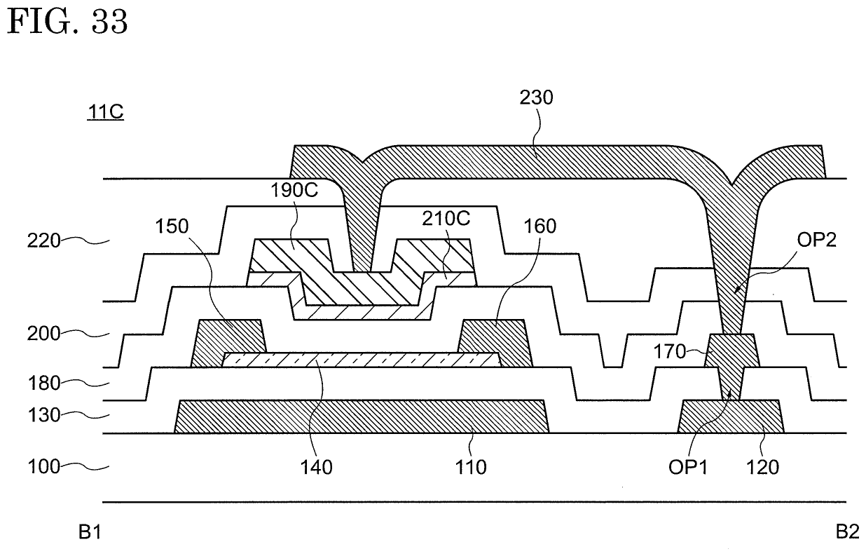

FIG. 32 is a schematic plan view showing a configuration of the semiconductor device 11C according to an embodiment of the present invention. FIG. 33 is a schematic cross-sectional view showing a configuration of the semiconductor device 11C according to an embodiment of the present invention. FIG. 33 is a cross-sectional view of the semiconductor device 11C cut along a line B1-B2 in FIG. 32.

As shown in FIG. 33, the semiconductor device 11C includes the first substrate 100, the first gate electrode 110, the scanning line 120, the first insulating layer 130, the oxide semiconductor layer 140, the source electrode 150, the drain electrode 160, the first connection electrode 170, the second insulating layer 180, a metal oxide layer 210C, a second gate electrode 190C, the nitride layer 200, a third insulating layer 220, and a second connection electrode 230. The metal oxide layer 210C is provided on the second insulating layer 180 so as to overlap the oxide semiconductor layer 140. The second gate electrode 190C is provided on and in contact with the metal oxide layer 210C. The second gate electrode 190C has substantially the same planar shape as the metal oxide layer 210C. That is, an edge surface of the second gate electrode 190C is substantially aligned with an edge surface of the metal oxide layer 210C. In a plan view, the metal oxide layer 210C and the second gate electrode 1900 do not overlap the first connection electrode 170. The nitride layer 200 is provided on the second insulating layer 180 so as to cover the edge surface of the metal oxide layer 210C and an upper surface and the edge surface of the second gate electrode 190C. The third insulating layer 220 is provided on the nitride layer 200. The second insulating layer 180, the nitride layer 200, and the third insulating layer 220 have a second opening portion OP2 through which a part of an upper surface of the first connection electrode 170 is exposed. Further, the nitride layer 200 and the third insulating layer 220 have a third opening portion OP3 through which a part of an upper surface of the second gate electrode 190 is exposed. The second connection electrode 230 is provided on the third insulating layer 220. The second connection electrode 230 is in contact with the first connection electrode 170 through the second opening portion OP2 and is in contact with the second gate electrode 190C through the third opening portion OP3.

As shown in FIG. 32, the second gate electrode 190C is provided to be spaced apart from the first connection electrode 170. However, as described above, the second connection electrode 230 is in contact with the first connection electrode 170 and the second gate electrode 1900. Thus, the second gate electrode 190C is electrically connected to the first gate electrode 110 via the first connection electrode 170 and the second connection electrode 230. Therefore, a voltage included in the signal input to the scan line 120 is applied to both the first gate electrode 110 and the second gate electrode 190C.

The third insulating layer 220 can function as an interlayer insulating layer. For example, the same material as the first insulating layer 130 and the second insulating layer 180 can be used for the third insulating layer 220. The third insulating layer 220 can also function as a planarizing layer. In this case, for example, a resin such as polyimide or acrylic can be used for the third insulating layer 220. The resin may be a photosensitive resin. When a photosensitive resin is used for the third insulating layer 220, etching can be performed by directly exposing the photosensitive resin to light without applying a resist, so that the process using the photolithography method is simplified. The third insulating layer 220 may have a single layer structure or a stacked structure. When the third insulating layer 220 has a stacked structure, the third insulating layer 220 may have a structure in which a resin is stacked on an oxide or a nitride.

The second connection electrode 230 has conductivity. The same material as the first connection electrode 170 can be used for the second connection electrode 230. Further, a transparent conductive material such as indium tin oxide (ITO) or indium zinc oxide (IZO) can also be used for the second connection electrode 230. Since the second connection electrode 230 is provided so as to overlap not only the source electrode 150 or the drain electrode 160 but also the scanning line 120, the aperture ratio of the pixel PX is hardly reduced. Therefore, not only a material having light-transmitting properties but also a material having no light-transmitting properties can be used for the second connection electrode 230.

### [2. Manufacturing Method of Semiconductor Device 11C]

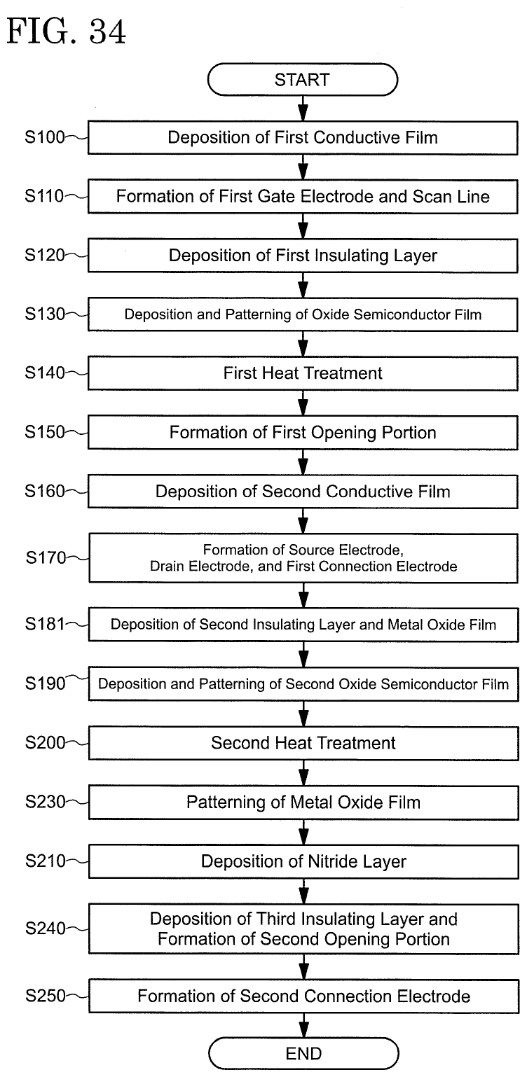

A method for manufacturing the semiconductor device 11C is described with reference to FIGS. 34 to 39.

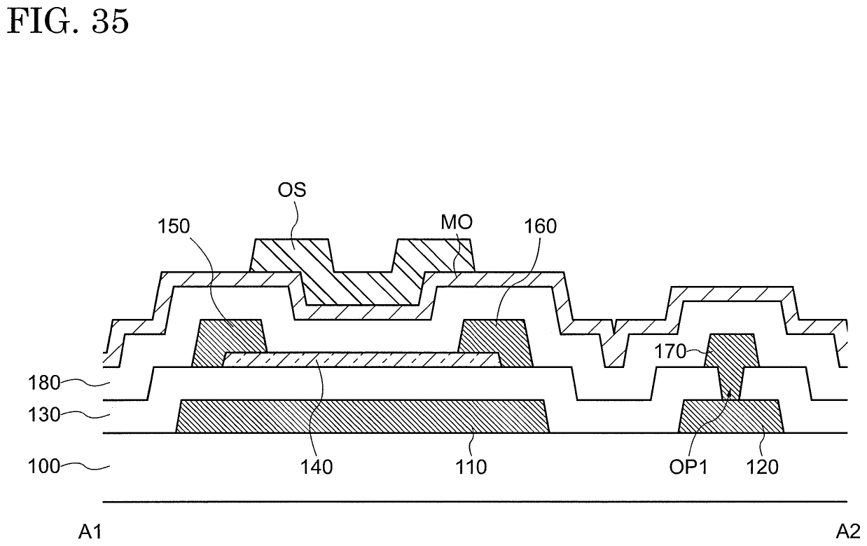

FIG. 34 is a flowchart illustrating a method for manufacturing the semiconductor device 11C according to an embodiment of the present invention. FIGS. 35 to 39 are schematic cross-sectional views illustrating a method for manufacturing the semiconductor device 11C according to an embodiment of the present invention. In the following description, each step of the flowchart shown in FIG. 34 is described in order.

Since steps S100 to S170 are similar to those described with reference to FIG. 26, the description thereof is omitted here. In the manufacture of the semiconductor device 11C, step S190 is performed after step S170.

In step S190, an oxide semiconductor film OS2 is deposited on the metal oxide film MO using a sputtering method. The conditions for depositing the oxide semiconductor film OS2 are as described above. Since the oxide semiconductor film OS2 has an amorphous structure, it is easy to etch the oxide semiconductor film OS2. Therefore, the oxide semiconductor film OS2 is patterned using a photolithography method (see FIG. 35). Step S200 is performed after step S190.

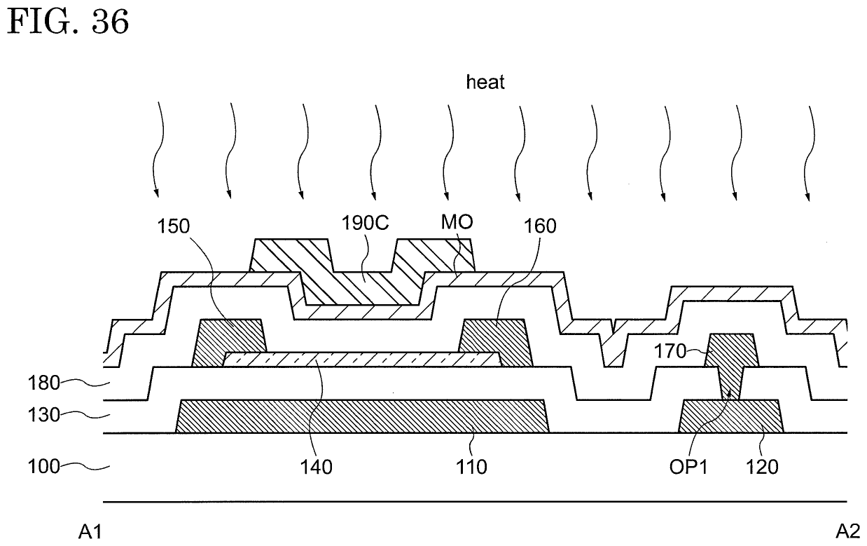

In step S200, a second heat treatment is performed on the oxide semiconductor layer 140 and the oxide semiconductor film OS2. In the second heat treatment, since the metal oxide film MO is formed so as to cover the second insulating layer 180, the metal oxide film MO suppresses oxygen in the second insulating layer 180 from being released to the outside, and oxygen can be efficiently supplied to the oxide semiconductor layer 140. Further, the oxide semiconductor film OS2 is crystallized by the second heat treatment, and a second gate electrode 190C containing Poly-OS is formed (see FIG. 36). The metal oxide film MO functions as a buffer layer, and the crystallinity of the second gate electrode 190C is controlled. Specifically, the size of the crystal grains included in the second gate electrode 1900 increases, and the degree of crystallinity of the second gate electrode 190C increases. Step S230 is performed after step S200.

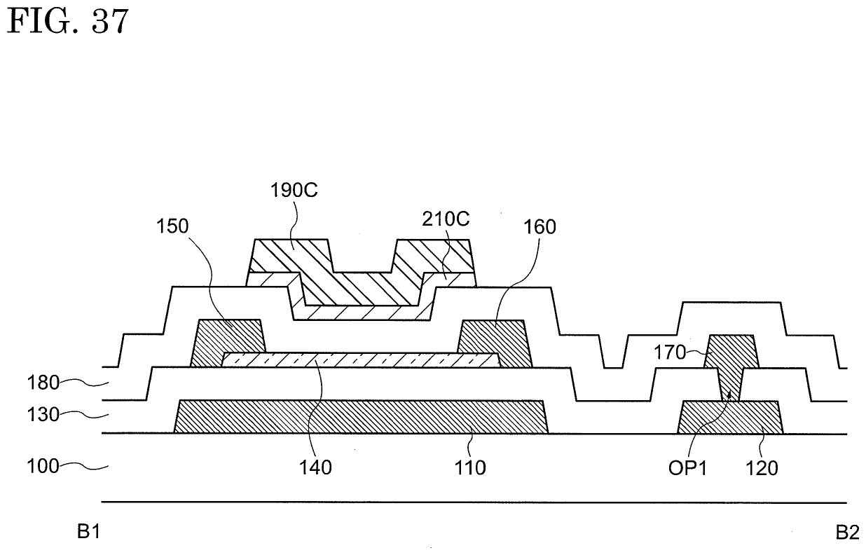

In step S230, the metal oxide film MO is patterned using the second gate electrode 190C as a mask to form the metal oxide layer 210C (see FIG. 37). The second gate electrode 190C containing Poly-OS has excellent etching resistance. Therefore, even when the metal oxide film MO is etched in the patterning of the metal oxide film MO, the second gate electrode 190C used as a mask is not etched. In the semiconductor device 11C, since the second gate electrode 190C can be used as a mask in the formation of the metal oxide layer 210C, a photolithography step can be omitted. Step S210 is performed after step S230.

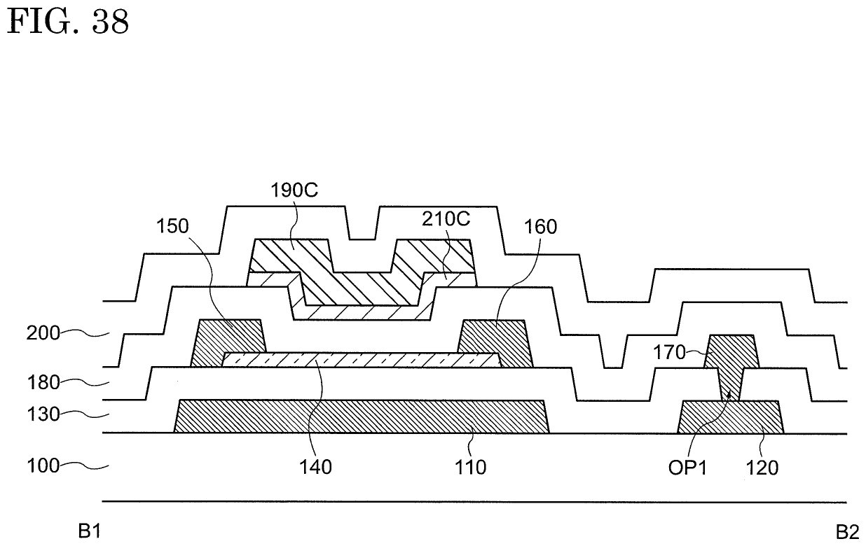

In step S210, a nitride layer 200 is deposited using a CVD method, a sputtering method, or an ALD method (see FIG. 38). Oxygen deficiencies are generated in the second gate electrode 190C, and hydrogen is diffused into the second gate electrode 190C and trapped in the oxygen deficiencies. As a result, the second gate electrode 190C has sufficiently low resistance. Step S240 is performed after step S210.

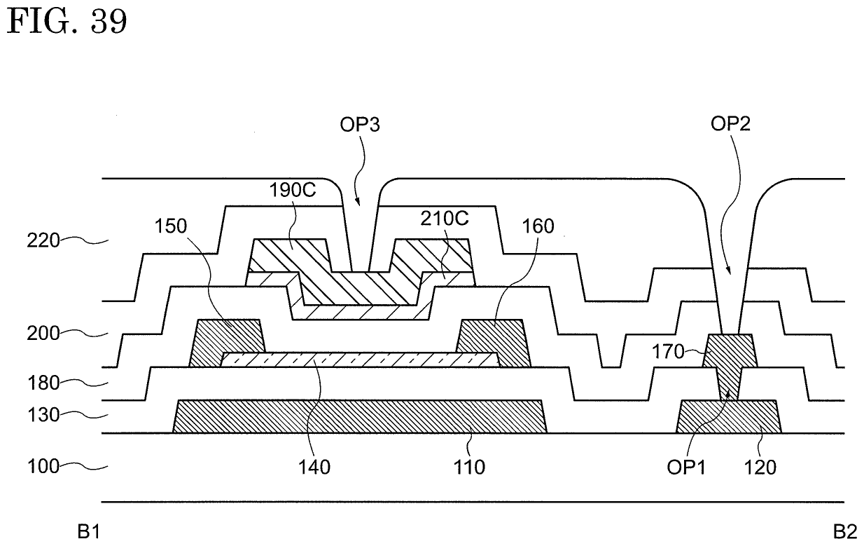

In step S240, the third insulating layer 220 is deposited on the second insulating layer 180 using a coating method. Further, the second opening portion OP2 penetrating the second insulating layer 180, the nitride layer 200, and the third insulating layer 220 and a third opening portion OP3 penetrating the nitride layer 200 and the third insulating layer 220 are formed using a photolithography method (see FIG. 39). When the third insulating layer 220 has photosensitivity, the second opening portion OP2 and the third opening portion OP3 can be formed without using a photoresist. A part of the first connection electrode 170 is exposed in the second opening portion OP2. A part of the second gate electrode 190C is exposed in the third opening portion OP3. Step S250 is performed after step S240.

In step S250, a fourth conductive film is deposited on the third insulating layer 220 using a sputtering method, and then the fourth conductive film is patterned using a photolithography method to form the second connection electrode 230. The second connection electrode 230 is in contact with the first connection electrode 170 through the second opening portion OP2 and in contact with the second gate electrode 190C through the third opening portion OP3.

The semiconductor device 11C shown in FIGS. 32 and 33 is manufactured by the above-described steps. The semiconductor device 11C manufactured in this manner has a high field effect mobility greater than or equal to 30 cm²/Vs.

In the semiconductor device 11C, since the second gate electrode 190 has light-transmitting properties, it is possible to suppress a reduction in the aperture ratio of the pixel PX. Further, according to the manufacturing method of the semiconductor device 11C, it is possible to repair oxygen deficiencies in the oxide semiconductor layer 140 containing Poly-OS and reduce the resistance of the second gate electrode 190 containing Poly-OS by a single heat treatment. Therefore, it is possible to suppress the manufacturing cost of the semiconductor device 11C. Further, the crystallinity of the second gate electrode 190 is increased by the metal oxide layer 210, and the second gate electrode 190 is stabilized. Therefore, the semiconductor device 11C has high reliability.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first gate electrode;
an oxide semiconductor layer comprising a first oxide semiconductor having a polycrystalline structure over the first gate electrode;
a source electrode and a drain electrode electrically connected to the oxide semiconductor layer; and
a second gate electrode overlapping the first gate electrode and the oxide semiconductor layer over the source electrode and the drain electrode,
wherein the second gate electrode comprises a second oxide semiconductor having a polycrystalline structure, and
the second gate electrode is electrically connected to the first gate electrode.

2. The semiconductor device according to claim 1, wherein a sheet resistance of the second gate electrode is less than or equal to 1000 Ω/sq.

3. The semiconductor device according to claim 1, wherein in a plan view, the second gate electrode overlaps at least one of the source electrode and the drain electrode.

4. The semiconductor device according to claim 1, wherein in a plan view, the second gate electrode is located with a space from each of the source electrode and the drain electrode.

5. The semiconductor device according to claim 1, wherein in a plan view, the second gate electrode extends so as to surround an edge portion of one of the source electrode and the drain electrode.

6. The semiconductor device according to claim 1, further comprising a metal oxide layer in contact with the second gate electrode under the second gate electrode.

7. The semiconductor device according to claim 6, further comprising a connection electrode in contact with the second gate electrode over the second gate electrode,
wherein the second gate electrode is electrically connected to the first gate electrode through the connection electrode.

8. The semiconductor device according to claim 1,
wherein the oxide semiconductor layer comprises:
a first region in contact with one of the source electrode and the drain electrode, and
a second region overlapping the second gate electrode between the source electrode and the drain electrode, and
a difference between a thickness of the first region and a thickness of the second region is less than or equal to 3 nm.

9. The semiconductor device according to claim 1, wherein an etching rate of the oxide semiconductor layer is less than 3 nm/min when the oxide semiconductor layer is etched using an etching solution containing phosphoric acid as a main component at 40° C.

10. The semiconductor device according to claim 9, wherein the etching solution further contains nitric acid and acetic acid.

11. The semiconductor device according to claim 9,
wherein the oxide semiconductor layer is formed by performing a heat treatment on an oxide semiconductor film having an amorphous structure, and
an etching rate of the oxide semiconductor film is greater than or equal to 100 nm/min when the oxide semiconductor film is etched using the etching solution at 40° C.

12. The semiconductor device according to claim 1, wherein an etching rate of the oxide semiconductor layer is less than 5 nm/min when the oxide semiconductor layer is etched using 0.5% of a hydrofluoric acid solution at room temperature.

13. The semiconductor device according to claim 1,
wherein each of the oxide semiconductor layer and the second gate electrode comprises a plurality of metal elements,
the plurality of metal elements comprises indium, and
an atomic ratio of indium to the plurality of metal elements is greater than or equal to 50%.

14. A method for manufacturing a semiconductor device comprising the steps of:
forming a first gate electrode;
forming an oxide semiconductor layer comprising a first oxide semiconductor having a polycrystalline structure over the first gate electrode;
forming a source electrode and a drain electrode each in contact with the oxide semiconductor layer;
depositing a first oxide semiconductor film over the source electrode and the drain electrode;
performing a heat treatment on the first oxide semiconductor film to form a second gate electrode comprising a second oxide semiconductor having a polycrystalline structure; and
depositing a nitride layer covering the second gate electrode.

15. The method for manufacturing a semiconductor device according to claim 14,
wherein the oxide semiconductor layer comprises:
a first region in contact with one of the source electrode and the drain electrode, and
a second region overlapping the second gate electrode between the source electrode and the drain electrode, and
a difference between a thickness of the first region and a thickness of the second region is less than or equal to 3 nm.

16. The method for manufacturing a semiconductor device according to claim 14, wherein an etching rate of the oxide semiconductor layer is less than 3 nm/min when the oxide semiconductor layer is etched using an etching solution containing phosphoric acid as a main component at 40° C.

17. The method for manufacturing a semiconductor device according to claim 16, wherein the etching solution further contains nitric acid and acetic acid.

18. The method for manufacturing a semiconductor device according to claim 16,
wherein the oxide semiconductor layer is formed by performing a heat treatment on an oxide semiconductor film having an amorphous structure, and
an etching rate of the oxide semiconductor film is greater than or equal to 100 nm/min when the oxide semiconductor film is etched using the etching solution at 40° C.

19. The method for manufacturing a semiconductor device according to claim 14, wherein an etching rate of the oxide semiconductor layer is less than 5 nm/min when the oxide semiconductor layer is etched using 0.5% of a hydrofluoric acid solution at room temperature.

20. The method for manufacturing a semiconductor device according to claim 14,
wherein each of the oxide semiconductor layer and the second gate electrode comprises a plurality of metal elements,
the plurality of metal elements comprises indium, and
an atomic ratio of indium to the plurality of metal elements is greater than or equal to 50%.
